(19) United States
(12) Patent Application Publication
(10) Pub. No.: US 2023/0321696 A1
(43) Pub. Date: Oct. 12, 2023

(54) SUBSTRATE PROCESSING SYSTEM AND SUBSTRATE PROCESSING METHOD

(71) Applicant: EBARA CORPORATION, Tokyo (JP)

(72) Inventors: Hiroki TAKAHASHI, Tokyo (JP); Ban ITO, Tokyo (JP); Seungho YUN, Tokyo (JP); Kohei SATO, Tokyo (JP)

(21) Appl. No.: 18/128,892

(22) Filed: Mar. 30, 2023

(30) Foreign Application Priority Data
Apr. 7, 2022 (JP) 2022-063911
Jan. 18, 2023 (JP) 2023-005644

(51) Int. Cl. B08B 3/10; B08B 1/00; B08B 3/02; B08B 5/02; B24B 57/02

(52) U.S. Cl. CPC B08B 3/10; B08B 1/002; B08B 3/02; B08B 5/02; B24B 57/02; B08B 2205/00; B08B 2203/00

(57) ABSTRACT

A substrate processing system capable of supplying a processing liquid containing fine bubbles at a high concentration without generating large sized bubbles in a middle of a supply line of the processing liquid is disclosed. There is provided a substrate processing system comprising: a gas dissolved water generation tank; a chemical liquid dilution module; and a substrate processing module. The substrate processing module comprises a processing liquid supply nozzle configured to supply the processing liquid onto a substrate. The processing liquid supply nozzle has a decompression release portion configured to generate fine bubbles of a gas from a diluted chemical liquid. The processing liquid supply nozzle is configured to supply the diluted chemical liquid containing fine bubbles in a process scrubbing the substrate.

### CROSS REFERENCE TO RELATED APPLICATION

This document claims priorities to Japanese Patent Application No. 2022-063911 filed Apr. 7, 2022, and Japanese Patent Application No. 2023-005644 filed Jan. 18, 2023, the entire contents of which are hereby incorporated by reference.

### BACKGROUND

In a manufacture of semiconductor devices, in a CMP (Chemical Mechanical Polishing) apparatus for planarizing a front surface of a substrate, a cleaning process for removing a slurry adhering to the front surface and a back surface of the substrate using a cleaning liquid after polishing the front surface of the substrate using a suspension liquid (slurry) containing abrasive grains and a polishing aid and a drying process for removing droplets adhering to the front surface and the back surface of the substrate by the cleaning process are performed.

If the cleaning process is not appropriate, defects will occur in a structure of the device, which will result in defective characteristics of the device. Therefore, it is necessary to select a cleaning process method that reliably removes the slurry in a short time without causing destruction or corrosion of the device.

For example, as shown in the substrate cleaning method described in Japanese patent No. 5866227, a scrub cleaning by a roll or pencil shaped sponge member is applied, and the cleaning liquid consisting of various chemicals is supplied in the process of the scrub cleaning.

A substrate processing apparatus described in Japanese laid-open patent publication No. 2020-174081 is configured to supply a cleaning liquid containing highly effective nanobubbles inside a cleaning member (sponge member) to allow the cleaning liquid to reach from a front surface of the cleaning member onto the substrate when the substrate is scrub cleaned. A cleaning liquid supply section containing nanobubbles has a cleaning liquid supply source, a gas dissolution section, a filter, and a supply line. The cleaning liquid supply source regulates a degassed cleaning liquid at a predetermined concentration, and is connected to the supply line. The gas dissolution section dissolves a gas in the cleaning liquid by pressurizing the gas through a membrane, for example, to the cleaning liquid flowing in the supply line. At this time, it is possible to generate nanobubbles in the cleaning liquid by allowing the cleaning liquid to contain the gas to a supersaturated state.

However, in the substrate processing apparatus described in Japanese laid-open patent publication No. 2020-174081, the gas dissolution section dissolves the gas to the supersaturated state by pressurizing the gas through the membrane. Therefore, an excess gas component is generated as large bubbles in the cleaning liquid. There is a problem that large sized bubbles stay in a bent portion in a middle of the supply line, and significantly obstruct a flow of the cleaning liquid. As a countermeasure, it is necessary to add a mechanism for removing the large sized bubbles, such as providing a filter in the supply line. However, in a dissolution method via the membrane, it is necessary to reduce a pressure of the cleaning liquid below a certain value. On the other hand, since a saturated dissolved concentration of the gas also depends on the pressure of the liquid, there is a problem that it is difficult to dissolve a highly concentrated gas and generate highly concentrated bubbles.

### SUMMARY

Therefore, there are provided a substrate processing system and a substrate processing method capable of supplying a processing liquid containing highly concentrated fine bubbles to a substrate to be processed without generating large sized bubbles in a middle of a processing liquid supply line.

Embodiments, which will be described below, relate to a substrate processing system and a substrate processing method, and more particularly to a substrate processing apparatus for polishing or cleaning a substrate.

In an embodiment, there is provided a substrate processing system comprising: a gas dissolved water generation tank configured to dissolve a gas in pure water at a first pressure; a chemical liquid dilution module configured to mix a chemical liquid and a gas dissolved water generated in the gas dissolved water generation tank at a predetermined volume ratio; and a substrate processing module configured to process a substrate, the substrate processing module comprises: a substrate holding mechanism configured to hold the substrate; a scrub processing member configured to contact the substrate and scrub the substrate, and a processing liquid supply nozzle configured to supply a processing liquid onto the substrate, the processing liquid supply nozzle has a decompression release portion that generates fine bubbles of the gas from a diluted chemical liquid by decompressing the diluted chemical liquid mixed in the chemical liquid dilution module from the first pressure to a second pressure, and the processing liquid supply nozzle supplies the diluted chemical liquid containing the fine bubbles in a process of scrubbing the substrate.

In an embodiment, the decompression release portion composes at least one or more orifice plates arranged in an internal flow path of the processing liquid supply nozzle or in a flow path immediately of the processing liquid supply nozzle, and the orifice plate reduces a pressure of the diluted chemical liquid to the second pressure by a pressure loss effect of the orifice plate, and simultaneously generates the fine bubbles.

In an embodiment, the substrate processing system comprises a gas supply source, a pure water supply source, and a water supply pump arranged in a flow path on upstream side of the gas dissolved water generation tank, and the water supply pump is configured to transfer pure water to the gas dissolved water generation tank so that a pressure in the gas dissolved water generation tank becomes the first pressure.

In an embodiment, the gas is composed of at least one or more of nitrogen, hydrogen, oxygen, ozone, carbon dioxide, neon, argon, xenon, and krypton.

In an embodiment, the substrate processing system comprises a liquid supply pump arranged in a flow path on upstream side of the chemical liquid dilution module, and the liquid supply pump is configured to transfer the chemical liquid to the chemical liquid dilution module to achieve the first pressure.

In an embodiment, the substrate processing module comprises a cleaning module, the chemical liquid is an undiluted cleaning liquid, and the scrub processing member comprises at least one of a sponge cleaning member and a buff cleaning member.

In an embodiment, the processing liquid supply nozzle, in the cleaning module, is arranged on a swinging arm configured to swing in a radial direction of the rotating substrate, and the processing liquid supply nozzle is configured to uniformly supply the cleaning liquid containing the fine bubbles from a center to a peripheral portion of the substrate.

In an embodiment, the processing liquid supply nozzle, in the cleaning module, is arranged on a self-cleaning position away from a position of the substrate, and the processing liquid supply nozzle is configured to supply the cleaning liquid containing the fine bubbles or the gas dissolved water containing the fine bubbles toward the scrub processing member waiting at the self-cleaning position.

In an embodiment, the substrate processing module comprises a polishing module, the chemical liquid is an undiluted slurry, and the scrub processing member comprises a polishing pad.

In an embodiment, the processing liquid supply nozzle, in the polishing module, is arranged above the rotating polishing pad, and the processing liquid supply nozzle is configured to supply the slurry containing the fine bubbles so as to infiltrate a contact interface between the rotating substrate and the polishing pad.

In an embodiment, the substrate processing system comprises a pure water supply nozzle having a decompression release portion configured to generate the fine bubbles from the gas dissolved water, and the decompression release portion extends in a radial direction of the polishing pad, and the pure water supply nozzle is configured to supply the gas dissolved water containing the fine bubbles during dressing of the polishing pad after terminating the polishing of the substrate.

In an embodiment, the substrate processing system comprises a single or a plurality of gas dissolved water nozzles configured to supply the gas dissolved water containing the fine bubbles onto the polishing pad, and arranged on a nozzle arm configured to be able to swing in a radial direction of the polishing pad, and the gas dissolved water nozzle is configured to supply the gas dissolved water containing the fine bubbles onto the polishing pad while the substrate is in contact with the polishing pad after terminating polishing the substrate.

In an embodiment, there is provided a substrate processing method for processing a substrate, comprising, dissolving a gas in pure water in a gas dissolved water generation tank at a first pressure; mixing a chemical liquid and a gas dissolved water generated in the gas dissolved water generation tank m a chemical liquid dilution module at a predetermined volume ratio; passing a diluted chemical liquid mixed in the chemical liquid dilution module through a decompression release portion arranged in an internal flow path of a processing liquid supply nozzle or a flow path immediately before the processing liquid supply nozzle to generate fine bubbles of the gas from the diluted chemical liquid by decompressing a pressure from the first pressure to a second pressure; and supplying the diluted chemical liquid containing the fine bubbles in a process of scrubbing the substrate.

In an embodiment, the gas is composed of at least one or more of nitrogen, hydrogen, oxygen, ozone, carbon dioxide, neon, argon, xenon, and krypton.

In an embodiment, the chemical liquid is an undiluted cleaning liquid, and the substrate processing method comprises supplying the diluted chemical liquid containing the fine bubbles while bringing a scrub processing member comprising at least one of a sponge cleaning member and a buff cleaning member into contact with the substrate.

In an embodiment, the chemical liquid is an undiluted slurry, and the substrate processing method comprises supplying the diluted chemical liquid containing the fine bubbles while bringing a scrub processing member comprising a polishing pad into contact with the substrate.

In an embodiment, supplying the gas dissolved water containing the fine bubbles from a pure water supply nozzle having a decompression release portion configured to generate the fine bubbles from the gas dissolved water during dressing of the polishing pad after terminating the polishing of the substrate.

In an embodiment, supplying the gas dissolved water containing the fine bubbles from a single or a plurality of gas dissolved water nozzles onto the polishing pad while the substrate is in contact with the polishing pad after polishing of the substrate, and the gas dissolved water nozzle is configured to supply the gas dissolved water containing the fine bubbles, and is arranged in a nozzle arm configured to be able to swing in a radial direction of the polishing pad.

In an embodiment, transporting the scrub processing member to a self-cleaning position away from a position of the substrate after scrubbing the substrate; and supplying a cleaning liquid containing the fine bubbles or a gas dissolved water containing the fine bubbles toward the scrub processing member waiting at the self-cleaning position.

The processing liquid supply nozzle has the decompression release portion that generates the fine bubbles of the gas. Therefore, large sized bubbles are not generated in the middle of the supply line, and the fine bubbles are generated near a use point where the substrate is processed. As a result, a chemical liquid containing the fine bubbles at a high concentration can be supplied to the substrate to be processed.

### BRIEF DESCRIPTION OF THE DRAWINGS

FIG. 1 is a plan view showing an overall configuration of a substrate processing apparatus;

FIG. 2 is a view showing a substrate processing system;

FIG. 3 is a view showing a first cleaning module;

FIG. 4 is a view showing a second cleaning module;

FIG. 5 is a view showing an embodiment of a mechanism for supplying a diluted chemical liquid containing fine bubbles in the first cleaning module:

FIG. 6 is a view showing an embodiment of a mechanism for supplying the diluted chemical liquid containing fine bubbles in the second cleaning module:

FIG. 7 is a view showing another embodiment of the substrate processing system;

FIG. 8 is a view showing a polishing module:

FIG. 9 is a view showing an embodiment of a mechanism for supplying a slurry containing fine bubbles in the polishing module:

FIG. 10 is a view showing a cleaning process of a front surface and a back surface of a substrate by the first cleaning module;

FIG. 11 is a view showing the cleaning process of the front surface and the back surface of the substrate by the second cleaning module:

FIG. 12 is a view showing the polishing process of the substrate by the polishing module;

FIG. 13 is a view showing an effect of cleaning the substrate with the cleaning liquid containing fine bubbles;

FIG. 14 is a view showing an effect of polishing the substrate with the slurry containing fine bubbles;

FIG. 15 is a view showing the liquid supply mechanism;

FIG. 16 is a view showing a processing flow of the substrate by a controller;

FIG. 17 is a view showing another embodiment of a polishing apparatus;

FIG. 18 is a view showing another embodiment of the processing flow of the substrate by the controller;

FIG. 19 is a view showing another embodiment of the first cleaning module;

FIG. 20 is a cross-sectional view showing the first cleaning module shown in FIG. 19;

FIG. 21 is view showing another embodiment of the second cleaning module; and

FIG. 22 is a cross-sectional view of the second cleaning module shown in FIG. 21.

### DESCRIPTION OF EMBODIMENTS

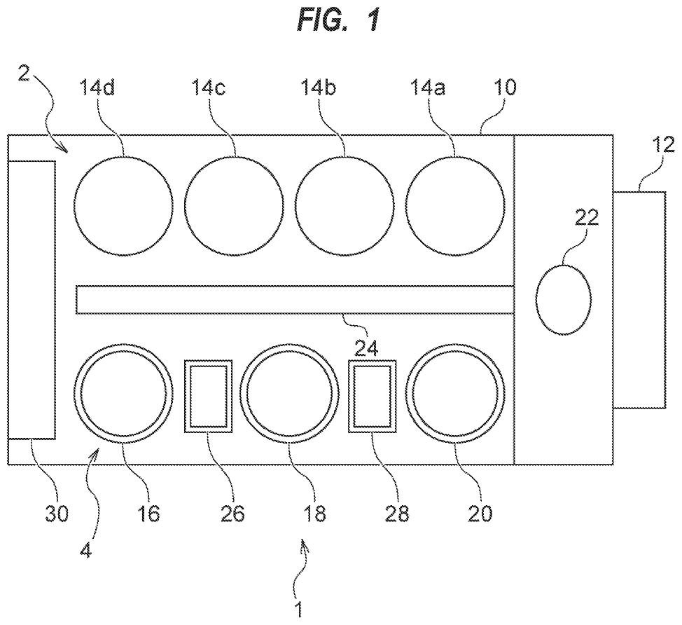

FIG. 1 is a plan view showing an overall configuration of a substrate processing apparatus. As shown in FIG. 1, the substrate processing apparatus 1 includes a housing 10 and a load port 12 on which substrate cassettes stocking a large number of substrates such as semiconductor wafers are placed. The load port 12 is arranged adjacent to the housing 10.

The substrate processing apparatus 1 includes a polishing section 2 and a cleaning section 4 arranged inside the housing 10. The polishing section 2 includes a plurality of (four in this embodiment) polishing modules 14a to 14d. The cleaning section 4 includes a first cleaning module 16 and a second cleaning module 18 for cleaning the polished substrate, and a drying module 20 for drying the cleaned substrate.

The polishing modules 14a to 14d are arranged along a longitudinal direction of the substrate processing apparatus 1. Similarly, the first cleaning module 16, the second cleaning module 18 and the drying module 20 are arranged along the longitudinal direction of the substrate processing apparatus 1.

The substrate processing apparatus 1 includes a first transport robot 22 arranged adjacent to the load port 12, and a transport modules 24 arranged adjacent to the polishing modules 14a to 14d. The first transport robot 22 receives the substrate before polishing from the load port 12, transports it to the transport module 24, and receives the substrate after drying from the drying module 20, and returns it to the load port 12. The transport module 24 transports the substrate received from the first transport robot 22, and transports the substrate between each of the polishing modules 14a to 14d.

The substrate processing apparatus 1 includes a second transport robot 26 arranged between the first cleaning module 16 and the second cleaning module 18, and a third transport robot 28 arranged between the second cleaning module 18 and the drying module 20. The second transport robot 26 transports the substrate between the transport module 24 and each of the cleaning modules 16 and 18. The third transport robot 28 transports the substrate between the modules 18 and 20.

The substrate processing apparatus 1 includes a controller 30 arranged inside the housing 10. The controller 30 is configured to control a movement of each device of the substrate processing apparatus 1. In this embodiment, the controller 30 is particularly configured to control an operation of a substrate processing system 50, which will be described later.

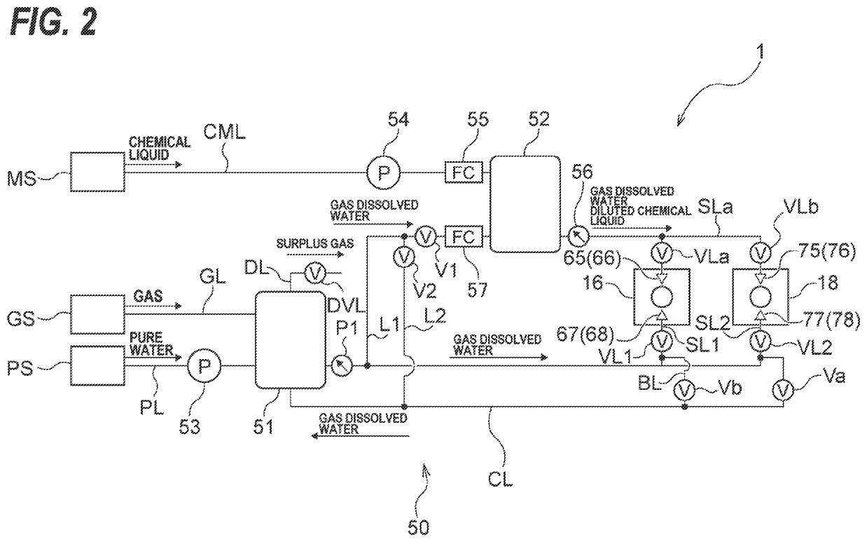

FIG. 2 is a view showing a substrate processing system. The substrate processing apparatus 1 includes a substrate processing system 50. The substrate processing system 50 includes a gas dissolved water generation tank 51 that dissolves a gas in pure water at a first pressure, a chemical liquid dilution module 52 that mixes the chemical liquid and the gas dissolved water at a predetermined volume ratio, and a substrate processing module for processing the substrate. In one embodiment, the chemical liquid may be a heated chemical liquid.

In this embodiment, the substrate processing system 50 includes, as the substrate processing module, the first cleaning module 16 and the second cleaning module 18 that clean the substrate. In one embodiment, the substrate processing system 50 may include one of the first cleaning module 16 and the second cleaning module 18.

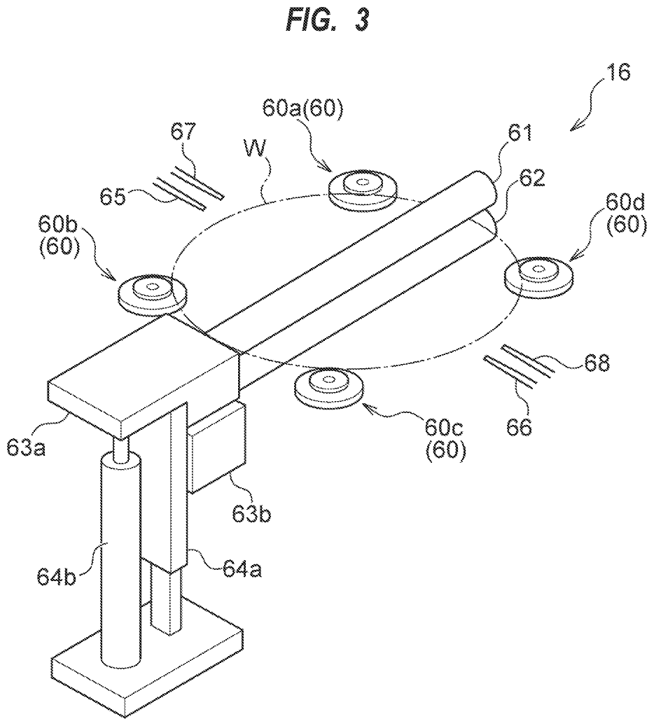

FIG. 3 is a view showing a first cleaning module. As shown in FIG. 3, the first cleaning module 16 includes a substrate holding mechanism 60 that holds and rotates the substrate W, and scrub processing members (in this embodiment, cleaning member) 61 and 62 that contact the substrate W and scrub the substrate W. The first cleaning module 16 further includes processing liquid supply nozzles (in this embodiment, chemical liquid supply nozzle) 65 and 66 that supply a processing liquid (in this embodiment, diluted chemical liquid) onto a front surface and a back surface of the substrate W, and processing liquid supply nozzles (in this embodiment, pure water supply nozzle) 67 and 68 that supply a processing liquid (in this embodiment, pure water) onto the front surface and the back surface of the substrate W.

Each of the cleaning members 61 and 62 is a sponge member having a cylindrical shape and a length in the longitudinal direction longer than a diameter of the substrate W. As a material of the sponge member, a highly hydrophilic material such as PU (polyurethane) or PVAc (polyvinyl acetal) is desirable. In one embodiment, each of the cleaning members 61 and 62 may be a buff cleaning member.

Each of the cleaning members 61 and 62 is arranged so that a direction of a central axis of each of the cleaning members 61 and 62 is parallel to the surfaces (i.e., the front surface and the back surface) of the substrate W. Hereinafter, the cleaning member 61 may be referred to as an upper roll cleaning member 61, and the cleaning member 62 may be referred to as a lower roll cleaning member 62.

The substrate holding mechanism 60 includes four rollers 60a to 60d that horizontally hold and rotate the substrate W with the front surface of the substrate W facing upward. The rollers 60a to 60d are configured to be movable in directions toward and away from each other by a drive mechanism (e.g., air cylinder) not shown. In this embodiment, the substrate holding mechanism 60 includes the rollers 60a to 60d as its components, but the substrate holding mechanism 60 is not limited to the rollers as long as it can hold a side surface of the substrate W. Instead of the rollers, for example, a plurality of clamps (not shown) may be provided. The clamp is configured to be movable between a position for holding a peripheral portion of the substrate W and a position away from the substrate W.

In one embodiment, the substrate holding mechanism 60 may be configured to hold the substrate W vertically. In this case, the rollers 60a to 60d (or clamps) are arranged vertically. The first cleaning module 16 includes rotating mechanisms 63a and 63b that rotate the upper roll cleaning member 61 and the lower roll cleaning member 62.

The upper roll cleaning member 61 and the lower roll cleaning member 62 are respectively supported by lifting mechanisms 64a and 64b, and are vertically movable by the lifting mechanisms 64a and 64b. An example of each of the lifting mechanisms 64a and 64b includes a motor drive mechanism using a ball screw or an air cylinder.

When the substrate W is transported in and out, the upper roll cleaning member 61 and the lower roll cleaning member 62 are separated from each other. When cleaning the substrate W, the upper roll cleaning member 61 and the lower roll cleaning member 62 move in a direction of proximity to each other, and come into contact with the front surface and the back surface of the substrate W. Thereafter, the upper roll cleaning member 61 and the lower roll cleaning member 62 rotate by the rotating mechanisms 63a and 63b to scrub (scrub cleaning) the substrate W, respectively.

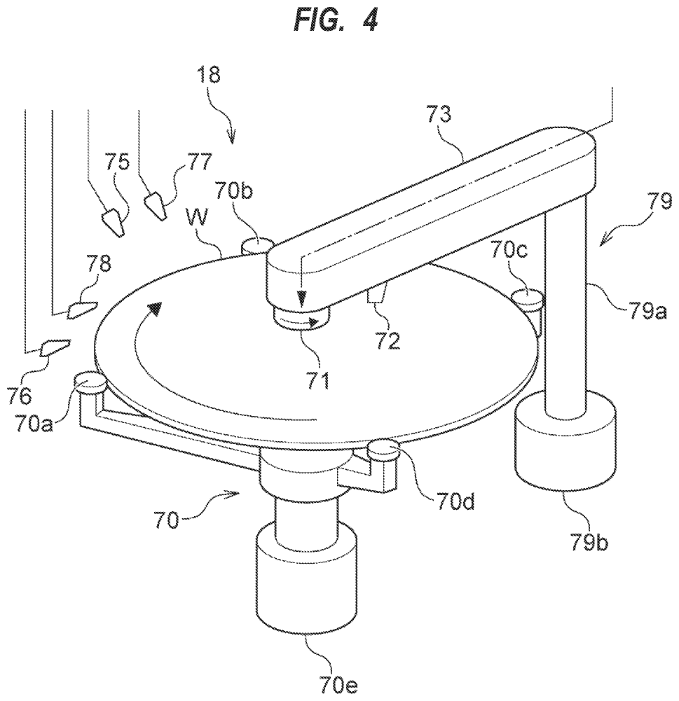

FIG. 4 is a view showing a second cleaning module. As shown in FIG. 4, the second cleaning module 18 includes a substrate holding mechanism 70 that holds and rotates the substrate W, and a scrub processing member (in this embodiment, a cleaning member) 71 that contacts the substrate W and scrubs the substrate W. The second cleaning module 18 further includes an arm (more specifically, swinging arm) 73 coupled to the cleaning member 71, and an arm swinging mechanism 79 that horizontally swings the arm 73. The second cleaning module 18 further includes processing liquid supply nozzles (in this embodiment, chemical liquid supply nozzles) 75 and 76 that supply a processing liquid (in this embodiment, diluted chemical liquid) onto the front surface and the back surface of the substrate W, and processing liquid supply nozzles (in this embodiment, pure water supply nozzles) 77 and 78 that supply a processing liquid (in this embodiment, pure water) onto the front surface and the back surface of the substrate W.

The substrate holding mechanism 70 includes chucks 70a to 70d that holds the peripheral portion of the substrate W, and a motor 70e coupled to the chucks 70a to 70d. The chucks 70a to 70d hold the substrate W, and the substrate W is rotated about its axis by driving the motor 70e.

The cleaning member 71 is a sponge member, which has a pencil shape, and contacts the front surface of the substrate W while rotating around a central axis of the cleaning member 71 to scrub the substrate W. Hereinafter, the cleaning member 71 may be referred to as a pencil cleaning member 71.

The arm 73 is arranged above the substrate W, and coupled to the arm swinging mechanism 79. The arm swinging mechanism 79 includes a swivel shaft 79a, and a rotating mechanism 79b. One end of the arm 73 is coupled to the swivel shaft 79a, and the other end of the arm 73 is coupled to the pencil cleaning member 71. A direction of the central axis of the pencil cleaning member 71 is perpendicular to the front surface (or back surface) of the substrate W.

The rotating mechanism 79b for swiveling the arm 73 is coupled to the swivel shaft 79a. The rotating mechanism 79b is configured to swivel the arm 73 within a plane parallel to the substrate W by rotating the swivel shaft 79a by a predetermined angle. The pencil cleaning member 71 moves in a radial direction of the substrate W as the arm 73 swivels. The swivel shaft 79a can be vertically moved by a lifting mechanism (not shown), and presses the pencil cleaning member 71 against the front surface of the substrate W at a predetermined pressure to scrub the substrate W (scrub cleaning). An example of the lifting mechanism includes a motor drive mechanism using a ball screw or an air cylinder.

As described above, the first cleaning module 16 supplies the chemical liquid onto the front surface and the back surface of the substrate W through the chemical liquid supply nozzles 65 and 66 when the roll cleaning member 61 and the lower roll cleaning member 62 are scrubbing the substrate W. Similarly, the second cleaning module 18 supplies the chemical liquid onto the front surface and the back surface of the substrate W through the chemical liquid supply nozzles 75 and 76 when the pencil cleaning member 71 is scrubbing the substrate W.

As shown in FIG. 2, the substrate processing system 50 includes a gas supply source GS and a pure water supply source PS arranged in a flow path on upstream side of the gas dissolved water generation tank 51, and a water supply pump 53. The water supply pump 53 is configured to transfer pure water to the gas dissolved water generation tank 51 so that a pressure in the gas dissolved water generation tank 51 becomes a predetermined pressure (i.e., a first pressure). In other words, a discharge pressure of the water supply pump 53 corresponds to the first pressure. The gas is composed of at least one or more components of nitrogen, hydrogen, oxygen, ozone, carbon dioxide, rare gases (neon, argon, xenon, krypton).

The substrate processing system 50 includes a gas line GL that connects the gas supply source GS and the gas dissolved water generation tank 51, and a pure water line PL that connects the pure water supply source PS and the gas dissolved water generation tank 51. The water supply pump 53 is connected to the pure water line PL.

When the gas and pure water are supplied to the gas dissolved water generation tank 51 through the gas line GL and the pure water line PL, respectively, the gas and pure water are mixed in the gas dissolved water generation tank 51 at the first pressure. The gas dissolved water, which is a mixture of the gas and pure water, is stored in the gas dissolved water generation tank 51.

A gas discharge line DL for discharging a surplus gas is connected to an upper portion of the gas dissolved water generation tank 51. A valve DVL is connected to the gas discharge line DL. When the valve DVL is opened, the surplus gas in the gas dissolved water generation tank 51 is discharged to an outside through the gas discharge line DL.

The substrate processing system 50 includes a circulation line CL that circulates the gas dissolved water in the gas dissolved water generation tank 51, a gas dissolved water supply line SL1 that supplies the gas dissolved water flowing through the circulation line CL to the pure water supply nozzles 67 and 68, and a gas dissolved water supply line SL2 that supplies the gas dissolved water flowing through the circulation line CL to the pure water supply nozzles 77 and 78. A pressure gauge P1 is connected to the circulation line CL.

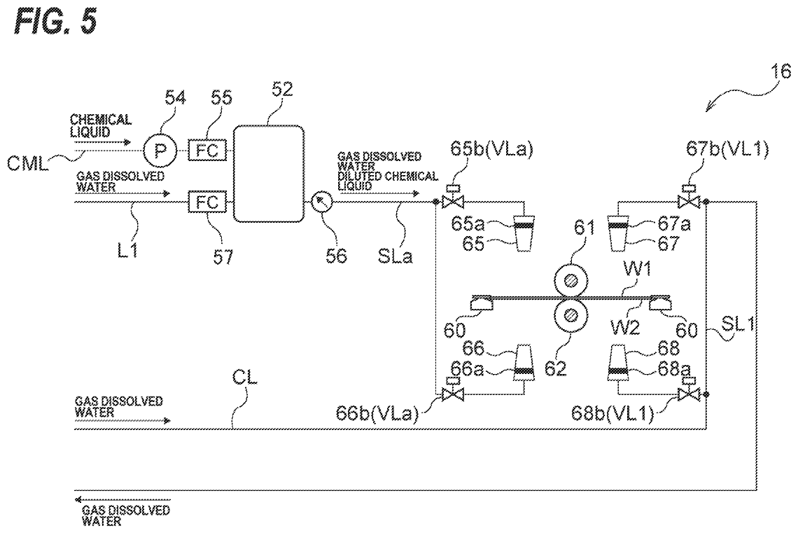

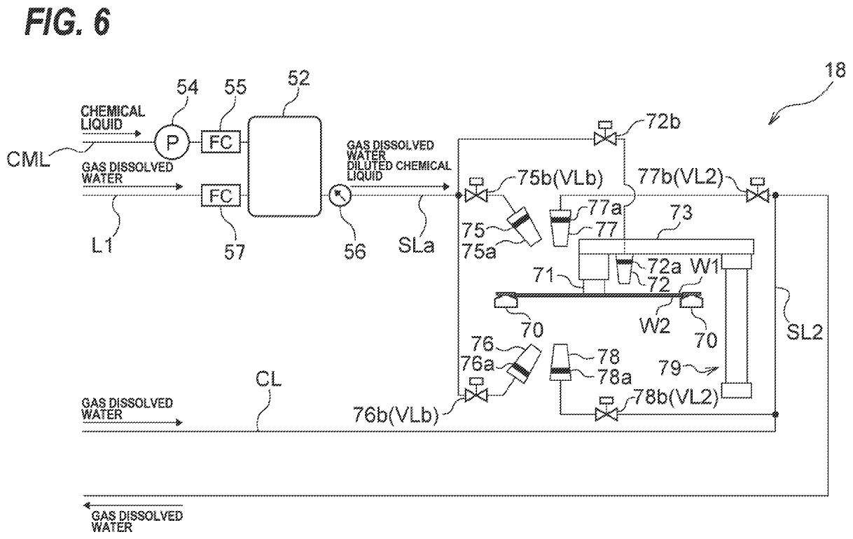

A valve VL1 is connected to the gas dissolved water supply line SL1, and a valve VL2 is connected to the gas dissolved water supply line SL2. The valve VL1 corresponds to valves 67b and 68b (see FIG. 5) described later, and the valve VL2 corresponds to valves 77b and 78b (see FIG. 6) described later.

The gas dissolved water in the gas dissolved water generation tank 51 circulates through the circulation line CL. When the gas dissolved water circulates through the circulation line CL, a bubble concentration of the gas contained in the gas dissolved water and/or a flow rate of the gas dissolved water are (is) stabilized.

As shown in FIG. 2, the substrate processing system 50 includes a valve Va arranged on downstream side of a connection portion of the supply line SL2 with the circulation line CL, the bypass line BL that connects the circulation line CL on downstream side of the valve Va and the supply line SL1, and a valve Vb connected to the bypass line BL. The valve Va is connected to the circulation line CL.

When the controller 30 closes the valves Va and Vb, and opens the valves VL1 and VL2, the gas dissolved water flowing through the circulation line CL is supplied onto the substrate W through the pure water supply nozzles 67, 68, 77 and 78, respectively.

In one embodiment, the substrate processing system 50 may include an air bubble concentration meter and/or flow meter connected to the circulation line CL. With such a configuration, the controller 30 can control opening/closing operations of the valves VL1 and VL2 based on signals detected by the bubble concentration meter and/or the flow meter.

The bypass line BL is arranged to shorten a circulation flow path of the circulation line CL. By closing the valves VL1, VL2 and Va, and opening the valve Vb, the gas dissolved water circulates between a portion of the circulation line CL and the bypass line BL.

The substrate processing system 50 includes connection lines L1 and L2 for transferring the gas dissolved water flowing through the circulation line CL to the chemical liquid dilution module 52, and valves V1 and V2 connected to the connection lines L1 and L2.

The connection line L1 is a pipe that transfers the gas dissolved water to the chemical liquid dilution module 52. The connection line L1 connects the circulation line CL and the chemical liquid dilution module 52, and is arranged on upstream side of the connection line L2 in a flow direction of the gas dissolved water flowing through the circulation line CL. The connection line L2 is connected to the circulation line CL and the connection line L1. The connection line L2 is a pipe for returning the gas dissolved water to the gas dissolved water generation tank 51 via the circulation line CL when the gas dissolved water is not transferred to the chemical dilution module 52.

When the valve V1 is opened, and the valve V2 is closed, the gas dissolved water flowing through the circulation line CL is transferred to the chemical liquid dilution module 52 through the connection line L1. When the valve V1 is closed, and the valve V2 is opened, the gas dissolved water flowing through the circulation line CL is returned to the gas dissolved water generation tank 51 through the connection line L2 (and the connection line L1).

The substrate processing system 50 includes a chemical liquid supply source MS arranged in a flow path on upstream side of the chemical liquid dilution module 52, a chemical liquid line CML connecting the chemical liquid dilution module 52 and the chemical liquid supply source MS, a liquid supply pump 54 connected to the chemical liquid line CML. The liquid supply pump 54 is arranged in the flow path on upstream side of the chemical liquid dilution module 52, and is configured to transfer the chemical liquid to the chemical liquid dilution module 52 at a predetermined pressure (i.e., the first pressure). In this embodiment, the chemical liquid is an undiluted cleaning liquid.

As shown in FIG. 2, the substrate processing system 50 includes a flow rate controller 55 connected to the chemical liquid line CML, and a flow rate controller 57 connected to the connection line L1. The controller 30 measures a flow rate of the chemical liquid flowing through the chemical liquid line CML and a flow rate of the gas dissolved water flowing through the connection line L based on signals detected by the flow rate controllers 55 and 57 to control the flow rate of the chemical liquid and the flow rate of the gas dissolved water supplied to the chemical liquid line CML. In this manner, the controller 30 can mix the chemical liquid and the gas dissolved water in the chemical liquid dilution module 52 at a predetermined volume ratio.

The substrate processing system 50 includes a chemical liquid supply line SLa that supplies the diluted chemical liquid mixed in the chemical liquid dilution module 52 to the chemical liquid nozzles 65 and 66 and the chemical liquid nozzles 75 and 76, a pressure gauge 56 connected to the chemical liquid supply line SLa, and a valve VLa and a valve VLb connected to the chemical liquid supply line SLa. The valve VLa corresponds to valves 65b and 66b (see FIG. 5) described later, and the valve VLb corresponds to valves 75b and 76b (see FIG. 6) described later. A mechanism for supplying the chemical liquid containing fine bubbles onto the substrate W will be described below.

FIG. 5 is a view showing an embodiment of a mechanism for supplying the diluted chemical liquid containing fine bubbles in the first cleaning module. The first cleaning module 16 includes chemical liquid supply nozzles 65 and 66 that supply the diluted chemical liquid toward a front surface W1 and a back surface W2 of the substrate W. Each of the chemical liquid supply nozzles 65 and 66 is connected to the chemical liquid supply line SLa.

As shown in FIG. 5, each of the liquid chemical supply nozzles 65 and 66 has each of decompression release portions 65a and 66a that reduces the pressure of the diluted chemical liquid supplied from the chemical liquid dilution module 52. The decompression release portions 65a and 66a are arranged in internal flow paths of the chemical liquid supply nozzles 65 and 66, respectively.

The decompression release portions 65a and 66a are mechanisms capable of obtaining high pressure loss. An example of each of decompression release portions 65a and 66a includes an orifice plate. Each of the decompression release portions 65a and 66a is configured to generate the fine bubbles of the gas from the diluted chemical liquid by reducing the pressure of the diluted chemical liquid mixed in the chemical dilution module 52 from a first pressure (e.g., 0.4 to 0.5 MPa) to a second pressure (e.g., hydrostatic pressure (about 0.1 MPa)). The second pressure is smaller than the first pressure. The fine bubbles are a higher level concept that includes ultrafine bubbles (i.e., nanobubbles) and microbubbles.

More specifically, each of the decompression release portions 65a and 66a generates the fine bubbles of the gas from the diluted chemical liquid by a pressurized dissolution method in which the fine bubbles are generated by rapid decompression of gas dissolved water (i.e., saturated solution) mixed to saturation in the gas dissolved water generation tank 51. A surplus gas that is not dissolved in the gas dissolved water generation tank 51 is discharged to the outside through a gas discharge line DL.

When the diluted chemical liquid passes through the decompression release portions 65a and 66a, the pressure of the diluted chemical liquid is abruptly reduced, and the highly concentrated gas dissolved in the chemical liquid is generated as the fine bubbles by the high pressure action. As a result, the diluted chemical liquid containing the fine bubbles at a high concentration is supplied onto the substrate during the cleaning process (i.e., in the process of scrubbing the substrate).

In this embodiment, the decompression release portions 65a and 66a are arranged inside the chemical liquid supply nozzles 65 and 66. In one embodiment, the decompression release portions 65a and 66a may be provided in flow paths immediately before the chemical liquid supply nozzles 65 and 66 (i.e., in the chemical liquid supply line SLa closer to the chemical liquid supply nozzles 65 and 66 than the valves 65b and 66b). Similarly, in this embodiment, the dilute chemical liquid containing the fine bubbles at a high concentration can be generated.

The decompression release portions 65a and 66a are part of the components of the chemical liquid supply nozzles 65 and 66, and even if the decompression release portions 65a and 66a are arranged in the chemical liquid supply line SLa, the chemical liquid supply nozzles 65 and 66 have the decompression release portions 65a and 66a.

As shown in FIG. 5, the pure water supply nozzles 67 and 68 have decompression release portions 67a and 68a arranged in internal flow paths of the pure water supply nozzles 67 and 68 or flow paths immediately before the pure water supply nozzles 67 and 68 (i.e., chemical liquid supply line SL1 closer to the chemical supply nozzles 67 and 68 than the valves 67b and 68b). With such a configuration, pure water containing the fine bubbles at a high concentration can be supplied to the substrate being cleaned.

FIG. 6 is a view showing an embodiment of a mechanism for supplying the diluted chemical liquid containing fine bubbles in the second cleaning module. The second cleaning module 18 includes chemical liquid supply nozzles 75 and 76 that supply the diluted chemical liquid from a fixed position toward the front surface W1 and the back surface W2 of the substrate W, and a movable (mobile) chemical liquid supply nozzle 72 that supplies the diluted chemical liquid from a lower surface of the arm 73 toward the front surface W1 of the substrate W.

The mobile chemical liquid supply nozzle 72, like the pencil cleaning member 71, moves in the radial direction of the rotating substrate W by swiveling the swiveling arm 73. The mobile chemical supply nozzle 72 is positioned in front of the pencil cleaning member 71 in the process of the pencil cleaning member 71 moving from the center to the peripheral portion of the substrate W. In other words, the mobile chemical liquid supply nozzle 72 is positioned more forward than the pencil cleaning member 71 in the direction of rotation of the substrate W.

Each of the chemical liquid supply nozzles 72, 75, and 76 has each of decompression release portions 72a, 75a, and 76a that reduces the pressure of the diluted chemical liquid supplied from the chemical liquid dilution module 52. The decompression release portions 72a, 75a, and 76a are arranged in internal flow paths of the chemical liquid supply nozzles 72, 75, and 76, respectively. When the diluted chemical liquid passes through the decompression release portions 72a, 75a, and 76a, the highly concentrated gas dissolved in the diluted chemical liquid is generated as fine bubbles. In one embodiment, the decompression release portions 72a, 75a, and 76a may be arranged in the flow path immediately before the chemical liquid supply nozzles 72, 75, and 76.

Each of the pure water supply nozzles 77 and 78 may have each of a decompression release portions 77a and 78a arranged in the internal flow paths of the chemical liquid supply nozzles 77 and 78, respectively, or arranged in the flow path immediately before the pure water supply nozzles 77 and 78, respectively. Structures of the decompression release portions 72a, 75a, 76a, 77a and 78a are the same as structures of the decompression release portions 65a, 66a, 67a and 68a, so detailed description thereof will be omitted.

According to this embodiment, a highly concentrated gas is dissolved at a high pressure in the gas dissolved water generation tank 51, and the diluted chemical liquid is adjusted in the chemical liquid dilution module 52 while maintaining the high pressure. Furthermore, fine bubbles are generated in the decompression release portion near a processing liquid supply mechanism provided in the substrate processing module. Therefore, large sized bubbles are not generated in the middle of the supply lines SLa and SL1, and fine bubbles are generated near a use point where the substrate is processed. As a result, the substrate processing system 50 can supply the chemical liquid (and gas dissolved water) containing fine bubbles at a high concentration onto the substrate to be processed.

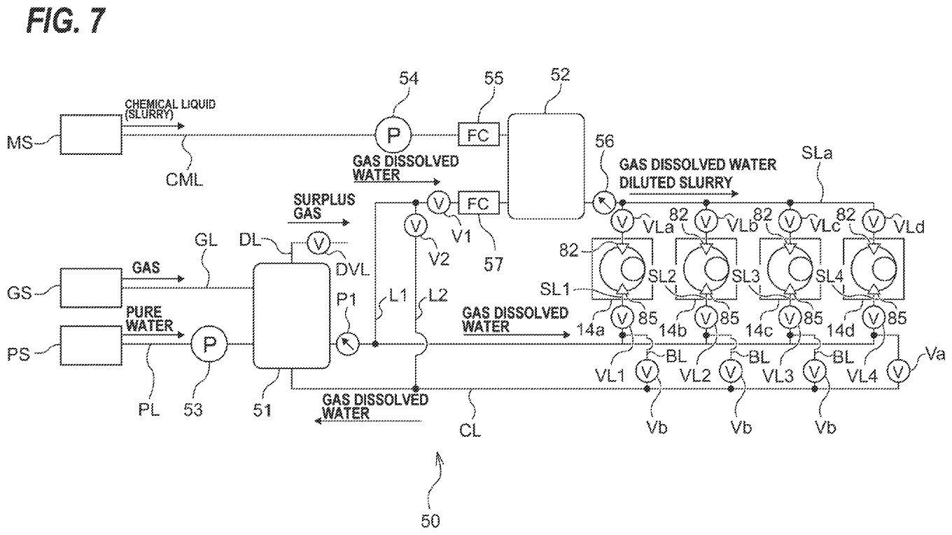

FIG. 7 is a view showing another embodiment of the substrate processing system. In the embodiment, the same reference numerals are assigned to the same structures as those of the above described embodiment, and duplicate descriptions are omitted.

As shown in FIG. 7, the substrate processing system 50 includes the gas dissolved water generation tank 51 that dissolves the gas in pure water at a first pressure, a chemical liquid dilution module 52 that mixes the chemical liquid (in this embodiment, undiluted slurry) and the gas dissolved water at a predetermined volume ratio, and polishing modules 14a to 14d that polish the substrate as the substrate processing module. In this embodiment, the substrate processing system 50 includes four polishing modules 14a to 14d, but in one embodiment, the substrate processing system 50 may include at least one polishing module 14.

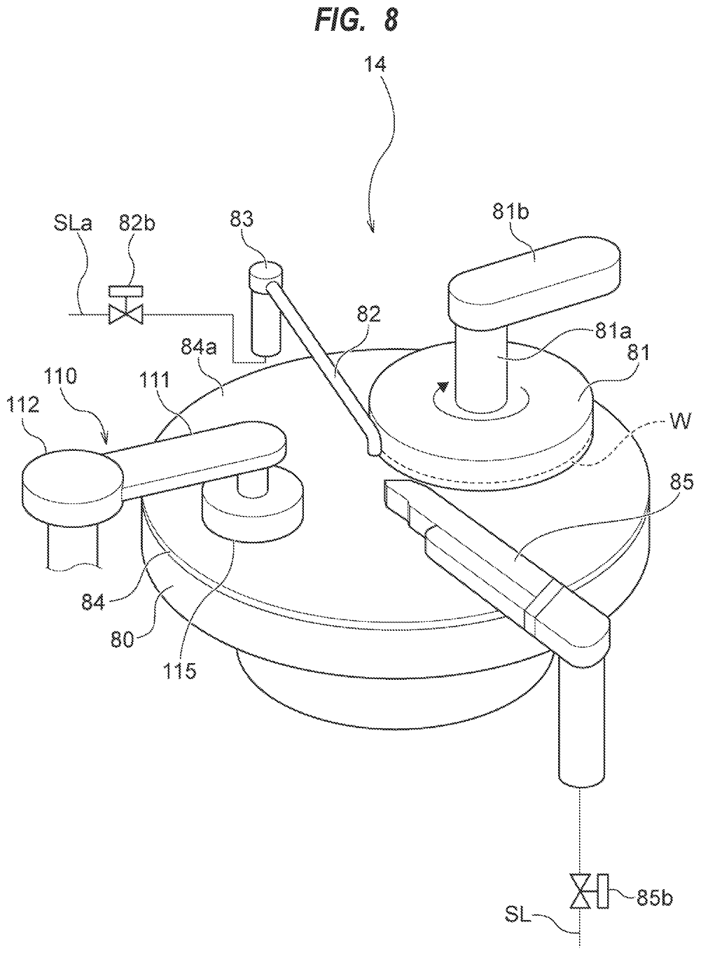

In this embodiment, the substrate processing system 50 includes a number of valves 82b (i.e., VLa, VLb, VLc, and VLd shown in FIG. 7) corresponding to the number of polishing modules 14a to 14d (see FIG. 8 to be described later). The valve 82b is connected to the chemical liquid supply line SLa.

Similarly, the substrate processing system 50 includes a number of gas dissolved water supply lines SL1, SL2, SL3, and SL4 and valves 85b (i.e., VL1, VL2, VL3, and VL4 shown in FIG. 7) corresponding to the number of polishing modules 14a to 14d (see FIG. 8 described later). The valve 85b is connected to each of the gas dissolved water supply lines SL1 to SL4. A bypass line BL is connected to each of the gas dissolved water supply lines SL1 to SL3.

FIG. 8 is a view showing the polishing module. In the embodiment described below, the polishing modules 14a to 14d may be collectively referred to as polishing modules 14, and the gas dissolved water supply lines SL1 to SL4 may be collectively referred to as gas dissolved water supply lines SL.

The polishing module 14 is configured to polish the substrate W using a polishing pad 84 having a polishing surface 84a as a scrub processing member. As shown in FIG. 8, the polishing module 14 includes a polishing table 80 that supports a polishing pad 84, a substrate holding mechanism (top ring) 81 that holds the substrate W to press it against the polishing surface 84a, a processing liquid supply nozzle (in this embodiment, a slurry supply nozzle) 82 that supplies the slurry onto a surface of the polishing surface 84a, and a processing liquid supply nozzle (in this embodiment, pure water supply nozzle) 85 that supplies pure water (i.e., gas dissolved water) for removing the slurry adhering to the surface of the polishing surface 84a. The pure water supply nozzle 85 is, in other words, an atomizer. Therefore, the pure water supply nozzle 85 may be referred to as an atomizer 85.

The polishing module 14 further includes a dressing device 110 for dressing the polishing pad 84. The dressing device 110 includes a dresser 115 that slides on the polishing surface 84a of the polishing pad 84, a dresser arm 111 that supports the dresser 115, and a dresser swivel shaft 112 that swivels the dresser arm 111. The dresser swivel shaft 112 is arranged outside the polishing pad 84.

The dresser 115 swings on the polishing surface 84a as the dresser arm 111 swivels. A lower surface of the dresser 115 constitutes a dressing surface composed of a large number of abrasive grains such as diamond grains. The dresser 115 rotates while swinging on the polishing surface to dress the polishing surface by slightly scraping off the polishing pad 84.

As shown in FIGS. 7 and 8, the slurry supply nozzle 82 is connected to the chemical liquid supply line SLa, and the atomizer 85 (i.e., pure water supply nozzle) is connected to the gas dissolved water supply line SL. Therefore, the slurry supply nozzle 82 supplies the diluted slurry containing fine bubbles onto the polishing pad 84 through the chemical liquid supply line SLa, and the atomizer 85 supplies the gas dissolved water containing fine bubbles through the gas dissolved water supply line SL. In one embodiment, the atomizer 85 may supply the gas dissolved water (megasonic water) excited by ultrasonic vibrations.

The polishing table 80 is formed in a shape of a disc, and is configured to be rotatable around its central axis as an axis of rotation. The polishing pad 84 is attached to an upper surface of the polishing table 80. The polishing pad 84 rotates integrally with the polishing table 80 as the polishing table 80 is rotated by a motor (not shown).

The top ring 81 holds the substrate W on a lower surface of the top ring 81 by vacuum suction or the like. The top ring 81 is configured to be rotatable together with the substrate W by power from a motor (not shown). An upper portion of the top ring 81 is connected to a support arm 81b via a shaft 81a. The top ring 81 can be vertically moved by an air cylinder (not shown) to adjust a distance from the polishing table 80. Thereby, the top ring 81 can press the held substrate W against the polishing surface 84a of the polishing pad 84.

The support arm 81b is configured to be able to swing by a motor, not shown, to move the top ring 81 in a direction parallel to the polishing surface 84a. In this embodiment, the top ring 81 is configured to be movable between a receiving position (not shown) of the substrate W and a position above the polishing pad 84, and also to be able to change a position of the substrate W pressed against the polishing pad 84.

A slurry supply nozzle 82 is provided above the polishing table 80, and supplies the slurry containing fine bubbles onto the polishing pad 84 supported by the polishing table 80. The slurry supply nozzle 82 is supported by the shaft 83. The shaft 83 is configured to be movable by a motor (not shown), and the slurry supply nozzle 82 can change a dropping position of the slurry during the polishing process. In this manner, the slurry supply nozzle 82 supplies the slurry containing fine bubbles so as to infiltrate a contact interface between the rotating substrate W and the polishing pad 84.

The atomizer 85 is provided above the polishing table 80, and arranged to extend along a radial direction of the polishing table 80. The atomizer 85 sprays the gas dissolved water containing fine bubbles toward the polishing pad 84 at a predetermined flow rate immediately after the polishing process of the substrate W with the slurry to wash away part of the slurry adhering to the polishing surface 84a and the substrate W.

The controller 30 is configured to control the overall operation of the polishing module 14. The controller 30 includes a CPU, memory, and other components, and may be configured as a microcomputer that uses software to achieve desired functions, or as a hardware circuit that performs dedicated arithmetic operations.

The controller 30 may be configured to estimate a polishing speed during the polishing process using artificial intelligence by machine learning in advance a correlation between a model number of the slurry, a model number of the polishing pad 84, output values of various sensors, a polishing process recipe, and an actual polishing speed in the past polishing processes.

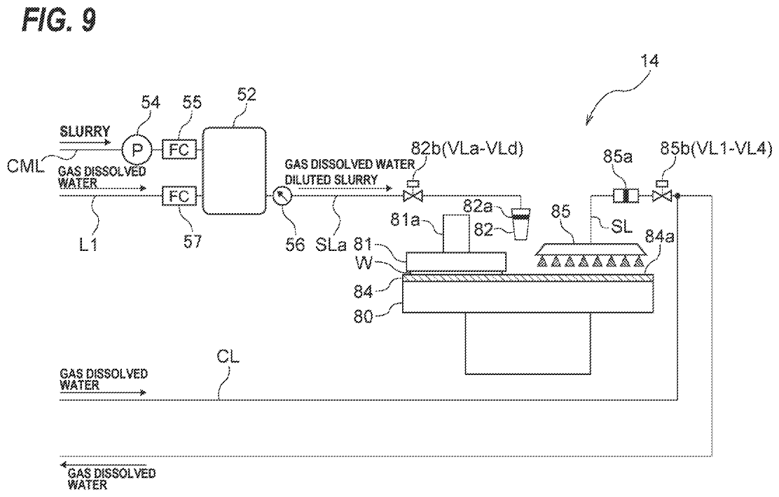

FIG. 9 is a view showing an embodiment of a mechanism for supplying the slurry containing fine bubbles in the polishing module. The polishing module 14 includes a slurry supply nozzle 82 that supplies the slurry toward the polishing surface 84a of the polishing pad 84. The slurry supply nozzle 82 has a decompression release portion 82a that reduces the pressure of the slurry supplied from the chemical liquid dilution module 52. The decompression release portion 82a is arranged in an internal flow path of the slurry supply nozzle 82. When the slurry passes through the decompression release portion 82a, the pressure of the slurry is abruptly lowered, and the high concentration of the gas dissolved in the slurry is generated as fine bubbles. As a result, the slurry containing a high concentration of fine bubbles is supplied to an interface between the polishing surface 84a and the substrate W during the polishing process.

The decompression release portion 82a may be provided in the flow path immediately before the slurry supply nozzle 82 (i.e., in the chemical liquid supply line SLa closer to the slurry supply nozzle 82 than the valve 82b). Similarly, in the embodiment, a dilute chemical liquid containing fine bubbles at a high concentration can be generated. The decompression release portion 82a is a part of the components of the slurry supply nozzle 82. Even if the decompression release portion 82a is arranged in the chemical liquid supply line SLa, the slurry supply nozzle 82 has the decompression release portion 82a.

As shown in FIG. 9, the atomizer 85 may have a decompression release portion 85a, which is arranged in an internal flow path of the atomizer 85 or in the flow path immediately before the atomizer 85 (i.e., in the gas dissolved water supply line SL closer to the atomizer 85 than the valve 85b). With such a configuration, pure water (i.e., gas dissolved water) containing fine bubbles at a high concentration can be supplied to the interface between the polishing surface 84a and the substrate W immediately after the slurry polishing process. The decompression release portion 85a is a part of the components of the atomizer 85, and even if the decompression release portion 85a is arranged m the gas dissolved water supply line SL, the atomizer 85 has the decompression release portion 85a.

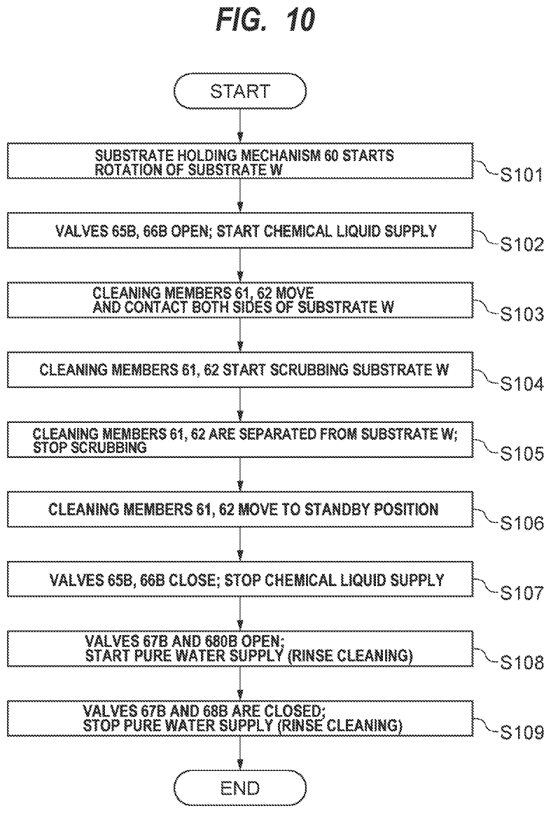

FIG. 10 is a view showing the cleaning process of the front surface and the back surface of the substrate by the first cleaning module. First, the substrate W waiting in the transport module 24 (see FIG. 1) is transported to the first cleaning module 16. A series of processes will be described below with reference to FIG. 5.

The substrate holding mechanism 60 holds the substrate W transported to the first cleaning module 16, and in this state, the rotation of the substrate W is started (see step S101). Thereafter, the controller 30 opens the valves 65b and 66b to start supplying the diluted chemical liquid containing fine bubbles at a high concentration onto the front surface W1 and the back surface W2 of the substrate W (see step S102). After the supply of the diluted chemical liquid containing fine bubbles at a high concentration is started, the controller 30 moves the cleaning members 61 and 62 from a predetermined standby position to a predetermined processing position to bring the cleaning members 61 and 62 into contact with both sides of the substrate W (see step S103).

Thereafter, the controller 30 starts scrubbing the cleaning members 61 and 62 against the substrate W (see step S104), and performs the scrub cleaning of the substrate W. After the scrub cleaning of the substrate W is terminated, the cleaning members 61 and 62 are away from the substrate W (see step S105), and the cleaning members 61 and 62 are moved to the standby position (see step S106).

Thereafter, the controller 30 closes the valves 65b and 66b to stop supplying of the diluted chemical liquid containing fine bubbles at a high concentration (see step S107). Thereafter, the controller 30 opens the valves 67b and 68b, starts supplying pure water containing fine bubbles at a high concentration (see step S108), and performs rinse cleaning the substrate W. After a certain period of time has passed, the controller 30 closes the valves 67b and 68b, and stops supplying pure water containing fine bubbles at a high concentration (see step S109).

Steps S106, S107, and S108 may be performed sequentially or simultaneously. If these steps are performed simultaneously, the substrate processing system 50 can realize a reduction in the cleaning sequence time.

In steps S102 to S107, pure water may be used instead of the diluted chemical liquid. In this case, the scrub cleaning of the substrate W is performed while pure water containing fine bubbles at a high concentration is supplied onto the front surface W1 and the back surface W2 of the substrate W. Therefore, since step S108 for removing the diluted chemical liquid remaining on the front surface W1 and the back surface W2 of the substrate W can be omitted, the substrate processing system 50 can shorten the time required for the series of cleaning sequences. In addition, the substrate processing system 50 can reduce the amount of chemical liquids used in a series of cleaning sequences, thereby reducing the environmental load.

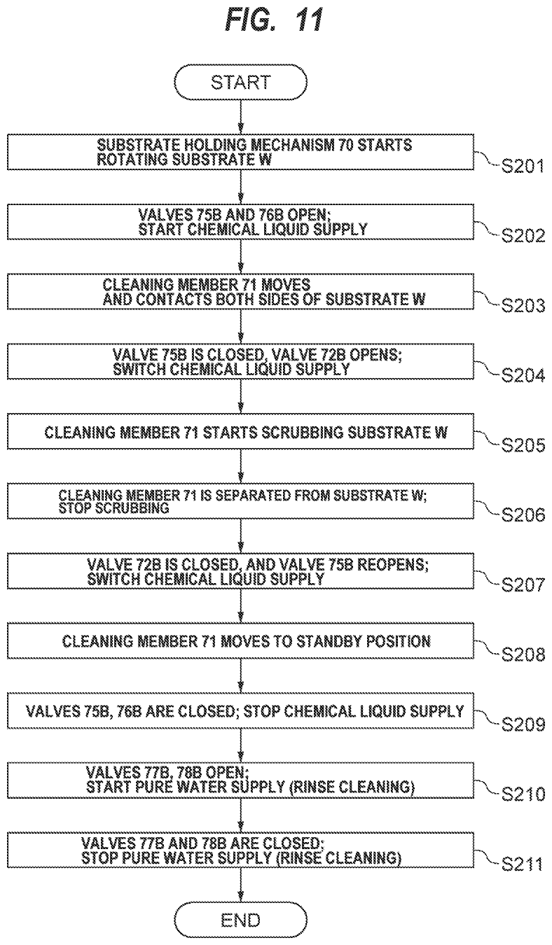

FIG. 11 is a view showing the cleaning process of the front surface and the back surface of the substrate by the second cleaning module. First, the substrate W that has terminated the cleaning processing in the first cleaning module 16 (see FIG. 1) is transported to the second cleaning module 18. A series of steps will be described below with reference to FIG. 6.

The substrate holding mechanism 70 holds the substrate W transported to the first cleaning module 18, and in this state, the rotation of the substrate W is started (see step S201). Thereafter, the controller 30 opens the valves 75b and 76b to start supplying the diluted chemical liquid containing fine bubbles at high concentration onto the front surface W1 and the back surface W2 of the substrate W (see step S202). After the supply of the diluted chemical liquid containing fine bubbles at a high concentration is started, the pencil cleaning member 71 moves from the standby position to the processing position by swiveling the arm 73, and contacts the front surface 1 of the substrate W (see step S203).

Thereafter, the controller 30 closes the valve 75b, opens the valve 72b (see FIG. 6) of the chemical liquid supply nozzle 72 (see step S204), and switches the supply nozzle for supplying the diluted chemical liquid containing fine bubbles at high concentration. Thereafter, the controller 30 swivels the arm 73 to move it in the radial direction of the substrate W, thereby starting scrubbing of the front surface W1 of the rotating substrate W with the cleaning member 71 (see step S205), and performing scrub cleaning of the substrate W.

After the scrub cleaning of the substrate W is terminated, the controller 30 separates the cleaning member 71 from the substrate W (see step S206), closes the valve 72b of the chemical liquid supply nozzle 72, and opens the valve 75b (see step S207). The controller 30 switches again the supply nozzle for supplying the diluted chemical liquid containing fine bubbles at a high concentration.

Thereafter, the pencil cleaning member 71 is moved to the standby position by swiveling the arm 73 (see step S208). The controller 30 then closes the valves 75b and 76b, and stops supplying the diluted chemical liquid containing fine bubbles at a high concentration (see step S209). Thereafter, the controller 30 opens the valves 77b and 78b, and starts supplying pure water containing fine bubbles at a high concentration (see step S210) to perform rinse cleaning of the substrate W. After a certain period of time elapses, the controller 30 closes the valves 77b and 78b to stop supplying pure water containing fine bubbles at a high concentration (see step S211).

Steps S208, S209, and S210 may be performed sequentially or simultaneously. When these steps are performed simultaneously, the substrate processing system 50 can shorten the time required for the series of cleaning sequences.

In steps S202 to S209, pure water may be used instead of the diluted chemical liquid. In this case, the front surface W1 scrubbing cleaning of the substrate W is performed with pure water containing fine bubbles at a high concentration supplied onto the front surface W1 and the back surface W2 of the substrate W. Therefore, step S210 for removing the diluted chemical liquid remaining on the front surface W1 and the back surface W2 of the substrate W can be omitted, and the substrate processing system 50 can shorten the time required for the series of cleaning sequences. In addition, the substrate processing system 50 can reduce the amount of chemical liquids used in a series of cleaning sequences, thereby reducing the environmental load.

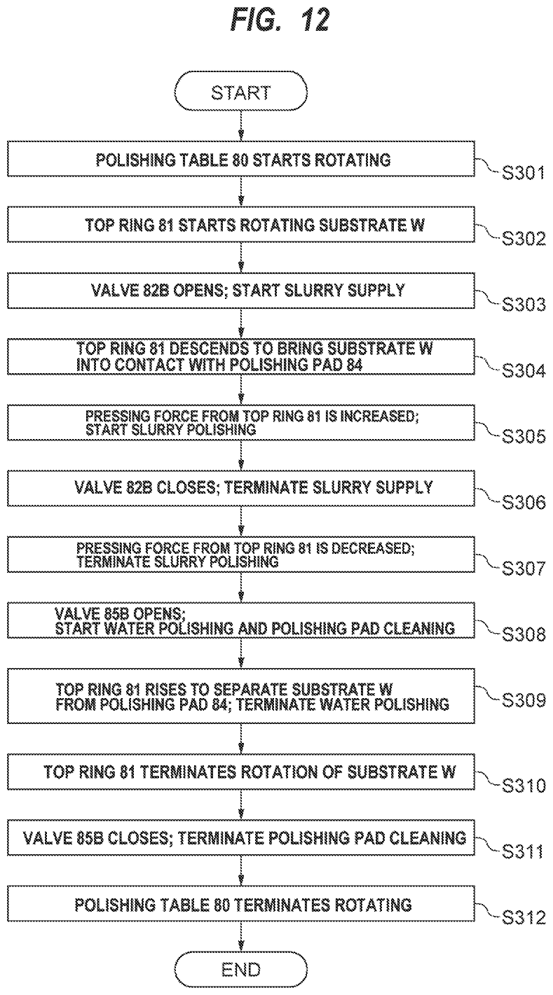

FIG. 12 is a view showing the polishing process of the substrate by the polishing module. First, the substrate before polishing that is housed in the load port 12 is transported to the polishing module 14 by the first transport robot 22 and the transport module 24. The series of processes are explained below with reference to FIG. 9.

The polishing table 80 starts rotating (see step S301), and the top ring 81 holding the substrate W starts rotating the substrate W (see step S302). Thereafter, the controller 30 opens the valve 82b, and starts supplying the slurry containing fine bubbles (see step S303).

After step S303, the controller 30 lowers the top ring 81 to bring the substrate W into contact with the polishing surface 84a of the polishing pad 84 (see step S304), and increases the pressing force applied from the top ring 81 to the substrate W to start slurry polishing (see step S305).

After a predetermined period of time has elapsed, the controller 30 closes the valve 82b to terminate supplying of the slurry (see step S306). Thereafter, the controller 30 decreases the pressing force applied from the top ring 81 to the substrate W to terminate slurry polishing of the substrate W (see step S307).

Thereafter, the controller 30 opens the valve 85b while the substrate W is in contact with the polishing pad 84 (more specifically, while pressing the substrate W against the polishing pad 84 at a positive pressure or while being the substrate W in contact with the polishing pad 84 at zero pressure), and supplies the gas dissolved water containing fine bubbles to start water polishing of the substrate W and cleaning of the polishing pad 84. The controller 30 then raises the top ring 81, and separates the substrate W from the polishing pad 84 to terminate water polishing of the substrate W (see step S309).

After step S309, the controller 30 terminates rotation of the substrate W by the top ring 81 (see step S310), closes the valve 85b, and terminates cleaning of the polishing pad 84 (see step S311). After step S311, the controller 30 terminates rotation of the polishing table 80 (see step S312).

As shown in FIG. 8, the polishing module 14 includes a dressing device 110. Therefore, after terminating water polishing of the substrate W, the controller 30 may open the valve 85b while moving the dresser 115 onto the polishing pad 84 to supply the gas dissolved water containing fine bubbles onto the polishing pad 84. In this manner, the atomizer 85 may supply the gas dissolved water containing fine bubbles onto the polishing pad 84 during dressing of the polishing pad 84 after terminating polishing of the substrate W.

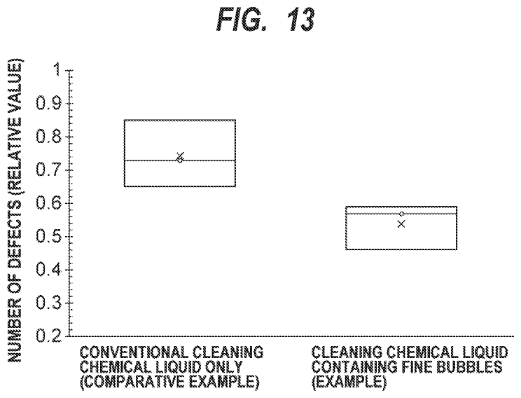

FIG. 13 is a view showing an effect of cleaning the substrate with the cleaning liquid containing fine bubbles. As is clear from FIG. 13, the number of defects when the substrate W is cleaned with the cleaning liquid containing fine bubbles is significantly less than the number of defects when the substrate W is cleaned with a conventional cleaning liquid (i.e., a cleaning liquid containing no fine bubbles). According to the embodiment, the substrate is scrub cleaned in the cleaning module while the cleaning liquid containing fine bubbles at a high concentration supplied. Therefore, the substrate processing system can obtain high particle removal performance.

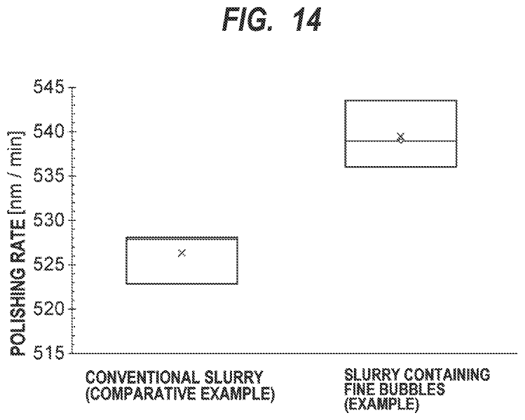

FIG. 14 is a view showing an effect of polishing the substrate with the slurry containing fine bubbles. As is clear from FIG. 14, the polishing rate when the substrate W is polished with the slurry containing fine bubbles is significantly higher than the polishing rate when the substrate W is polished with conventional slurry (i.e., slurry containing no fine bubbles). According to this embodiment, the substrate W is polished in the polishing module while the slurry containing fine bubbles at a high concentration supplied. Therefore, the substrate processing system 50 can obtain a high polishing rate.

Furthermore, according to this embodiment, a chemical liquid (cleaning liquid, slurry) containing fine bubbles of nitrogen gas or hydrogen gas at high concentration is supplied onto the substrate W. The chemical liquid containing fine bubbles can suppress the dissolution of atmospheric components during processing of the substrate W. Therefore, since polishing and cleaning processes are performed with a chemical liquid that has a low concentration of dissolved oxygen, corrosion of a metal film formed on the substrate W can be suppressed.

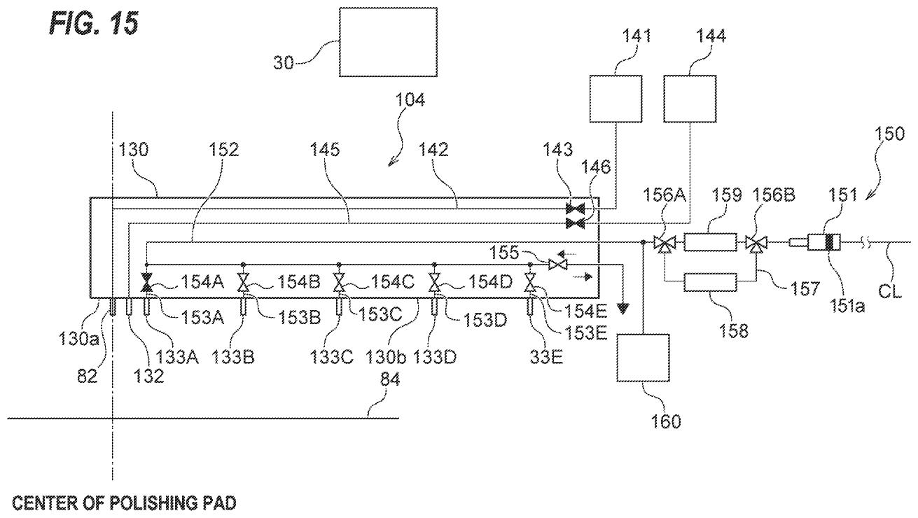

FIG. 15 is a view showing the liquid supply mechanism. An embodiment for controlling a size distribution of bubbles will be described below. As shown in FIG. 15, the substrate processing system 50 may include a liquid supply mechanism 104. The liquid supply mechanism 104 includes a radially movable nozzle arm 130 of the polishing table 80, a slurry supply nozzle 82 arranged at a tip portion 130a of the nozzle arm 130, and a pure water nozzle 132 and gas dissolved water nozzles 133A, 133B, 133C, 133D and 133E arranged at an arm portion 130b of the nozzle arm 130.

The nozzle arm 130 is coupled to a nozzle swivel axis (not shown) that swivels the nozzle arm 130. The nozzle swivel axis is arranged outside of the polishing pad 84. The nozzle arm 130 is configured to be movable between a retreat position outside the polishing pad 84 and a processing position above the polishing pad 84 by driving the nozzle swivel axis (more specifically, a motor connected to the nozzle swivel axis).

As shown in FIG. 15, when the nozzle arm 130 is in the processing position, the tip portion 130a of the nozzle arm 130 is arranged above the center of polishing pad 84. Therefore, the slurry supply nozzle 82 arranged at the tip portion 130a of the nozzle arm 130 is arranged above the center of the polishing pad 84 so that an injection port of the slurry supply nozzle 82 faces the center of the polishing pad 84.

When the nozzle arm 130 is in the processing position, each of the gas dissolved water nozzles 133A to 133E is arranged above an area so that an injection port of each of the gas dissolved water nozzles 133A to 133E faces the area between the center of the polishing pad 84 and the periphery of the polishing pad 84. The pure water nozzle 132 is arranged adjacent to the slurry supply nozzle 82, and the gas dissolved water nozzle 133A is arranged adjacent to the pure water nozzle 132.

The gas dissolved water nozzles 133A to 133E are arranged in this order from a tip side (i.e., tip portion 130a) of the nozzle arm 130 to a base side of the nozzle arm 130. Each of the gas dissolved water nozzles 133A to 133E may have a single tube shape or a spray nozzle shape.

In the embodiment shown in FIG. 15, the liquid supply mechanism 104 includes a plurality of (more specifically, five) gas dissolved water nozzles, but the number of gas dissolved water nozzles is not limited to this embodiment. In one embodiment, the liquid supply mechanism 104 may include one gas dissolved water nozzle or two or more gas dissolved water nozzles.

The liquid supply mechanism 104 includes a slurry line 142 connected to the slurry supply nozzle 82, an open/close valve 143 that opens and closes the slurry line 142, and a slurry supply source 141 that supplies the slurry to the slurry supply nozzle 82 through the slurry line 142. Similarly, the liquid supply mechanism 104 includes a pure water line 145 connected to the pure water nozzle 132, an open/close valve 146 that opens and closes the pure water line 145, and a pure water supply source 144 that supplies pure water to the pure water nozzle 132 through the pure water line 145.

The open/close valves 143 and 146 are electrically connected to the controller 30. When the controller 30 opens the open/close valve 143, the slurry is supplied from the slurry supply source 141 to the slurry supply nozzle 82 through the slurry line 142. Similarly, when the controller 30 opens the open/close valve 146, pure water is supplied from the pure water supply source 144 to the pure water nozzle 132 through the pure water line 145.

The substrate processing system 50 includes a gas dissolved water supply line 152 connected to the circulation line CL and the gas dissolved water nozzle 133A, a bypass line 157 connected to the gas dissolved water supply line 152, a micro bubble filter 159 connected to the gas dissolved water supply line 152, and an ultrafine bubble filter 158 connected to the bypass line 157.

The substrate processing system 50 includes a processing liquid supply nozzle 151 connected to the fine bubble liquid supply line 152. The processing liquid supply nozzle 151 has a decompression release portion 151a that generates fine bubbles of the gas from the gas dissolved water by decompressing the gas dissolved water flowing in the circulation line CL from a first pressure to a second pressure.

The substrate processing system 50 includes three way valves 156A and 156B that connect the bypass line 157 to the gas dissolved water supply line 152. Each of the three way valves 156A and 156B is electrically connected to the controller 30. The controller 30 can switch the flow of the gas dissolved water between a flow passing through the microbubble filter 159 and a flow passing through the ultrafine bubble filter 158 by operating each of the three way valves 156A and 156B.

The microbubble filter 159 allows a passage of microbubbles having bubble diameters from 1 micrometer to less than 100 micrometers, and traps (removes) bubbles larger in size than microbubbles. Therefore, when the gas dissolved water passes through the microbubble filter 159, the gas dissolved water containing microbubbles having bubble diameters from 1 micrometer to less than 100 micrometers is supplied.

The ultrafine bubble filter 158 allows a passage of ultrafine bubbles (i.e., nanobubbles) having a bubble diameter of 1 micrometer or less, and traps (removes) bubbles with larger in size than that of ultrafine bubbles. Therefore, when the gas dissolved water passes through the ultrafine bubble filter 158, the gas dissolved water containing ultrafine bubbles having a bubble diameter of 1 micrometer or less is supplied. In this manner, the substrate processing system 50 can supply the gas dissolved water containing microbubbles and the gas dissolved water containing ultrafine bubbles.

The substrate processing system 50 may further include a particle counter 160 arranged on downstream side of the three way valve 156A in a flow direction of the gas dissolved water. The particle counter 160 is configured to measure the number of bubbles in the gas dissolved water. Therefore, the substrate processing system 50 may supply the gas dissolved water from each of the gas dissolved water nozzles 133A to 133E based on the number of bubbles measured by the particle counter 160 after the number of bubbles in the gas dissolved water reaches a predetermined standard number. The gas dissolved water having bubbles that meet the predetermined standard number of bubbles can fully demonstrate its properties. In one embodiment, the particle counter 160 may be a laser diffraction and scattering bubble densitometer.

The substrate processing system 50 according to the embodiments shown in FIGS. 1 to 14 may include the particle counter 160 described above. In this case, the particle counter 160 is also arranged on downstream side of the decompression release portion.

As shown in FIG. 15, the ultrafine bubble filter 158 and the microbubble filter 159 are arranged adjacent to the nozzle arm 130 (more specifically, the gas dissolved water nozzles 133A to 133E). If a distance between the filters 158 and 159 and the gas dissolved water nozzles 133A to 133E is large, the bubbles in the gas dissolved water may disappear while the gas dissolved water moves to the gas dissolved water nozzles 133A to 133E. In this embodiment, it is possible to reliably prevent the bubbles contained in the gas dissolved water from disappearing.

The substrate processing system 50 includes branch lines 153A, 153B, 153C. 153D, and 153E connected to the gas dissolved water nozzles 133A to 133E. The substrate processing system 50 includes open/close valves 154A, 154B, 154C, 154D, and 154E connected to the branch lines 153A, 153B, 153C, 153D, and 153E, and an open/close valve 155 connected to the gas dissolved water supply line 152. The open/close valves 154A, 154B, 154C, 154D, and 154E and the open/close valve 155 are electrically connected to the controller 30. The controller 30 can control operations of each of the open/close valves 154A, 154B, 154C, 154D, and 154E and operations of the open/close valve 155.

When supplying the gas dissolved water from gas dissolved water nozzles 133A to 133E, the controller 30 opens the open/close valves 154A to 154E, and closes the open/close valve 155. By the operations, the gas dissolved water flowing through the gas dissolved water supply line 152 is supplied from the gas dissolved water nozzles 133A to 133E.

The open/close valves 154A to 154E correspond to the gas dissolved water nozzles 133A to 133E. Therefore, the controller 30 can arbitrarily select the gas dissolved water nozzles 133A to 133E to which the gas dissolved water should be supplied by controlling each of the open/close valves 154A to 154E.

For example, the controller 30 opens the open/close valve 154A, and closes the open/close valves 154B, 154C, 154D, 154E and 155. As a result, the gas dissolved water is supplied only from the gas dissolved water nozzle 133A. The controller 30 opens the open/close valve 155, and closes the open/close valves 154A, 154B, 154C, 154D, and 154E. The gas dissolved water is not supplied from any of the gas dissolved water nozzles 133A to 133E, but is discharged into the circulation line CL through the gas dissolved water supply line 152.

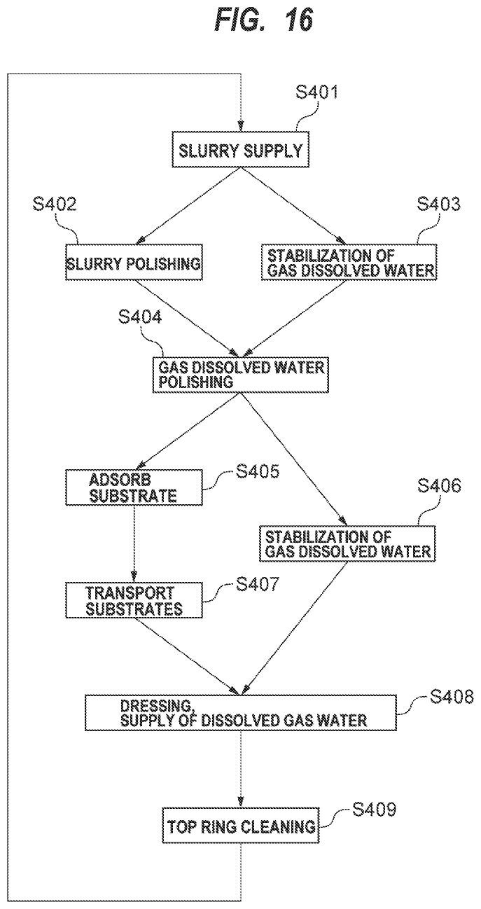

FIG. 16 is a view showing a processing flow of the substrate by the controller. The controller 30 operates the nozzle arm 130 to arrange the tip portion 130a of the nozzle arm 130 above the center of the polishing pad 84. The controller 30 opens the open/close valve 143 to supply the slurry on the polishing pad 84 while rotating the polishing table 80 (see step S401 in FIG. 16).

In one embodiment, the slurry containing fine bubbles may be supplied as described in the embodiments described above. The configuration for supplying the slurry containing fine bubbles may be the configuration according to the embodiment shown in FIG. 7, or the liquid supply mechanism 104 according to the embodiment shown in FIG. 15 may have a configuration for supplying the slurry containing fine bubbles.

In this state, the controller 30 presses the substrate W held by the top ring 81 against the polishing pad 84 while rotating the substrate W to slurry polish the substrate W (see step S402). In step S402, the controller 30 rotates the polishing pad 84 and the top ring 81 in the same direction to polish the substrate W.

At this time, the controller 30 performs a supply preparation for stable supplying the gas dissolved water in parallel with a polishing operation (i.e., step S402) of the substrate W (see step S403). More specifically, the controller 30 operates the three way valves 156A and 156B to open the bypass line 157 in order to supply the gas dissolved water. The gas dissolved water then passes through the ultrafine bubble filter 158 without passing through the microbubble filter 159, and as a result, the substrate processing system 50 supplies the gas dissolved water containing ultrafine bubbles.

When the controller 30 closes the open/close valves 154A to 154E, and opens the open/close valve 155, the gas dissolved water is returned to the circulation line CL through the gas dissolved water supply line 152 without being supplied from the gas dissolved water nozzles 133A to 133E. The controller 30 determines whether the number of bubbles in the gas dissolved water is stable based on the number of bubbles measured by the particle counter 160.

Therefore, the controller 30 closes the open/close valve 143 to terminate slurry polishing of the substrate W. After slurry polishing of the substrate W is terminated, the controller 30 starts water polishing (in this embodiment, gas dissolved water polishing) of the substrate W (see step S404). More specifically, the controller 30 opens at least one of the open/close valves 154A to 154E, closes the open/close valve 155, and supplies the gas dissolved water from at least one of the gas dissolved water nozzles 133A to 133E onto the polishing pad 84 while the substrate W is in contact with the polishing pad 84.

When the gas dissolved water is supplied onto the polishing pad 84, the bubbles contained in the gas dissolved water burst. An impact of the burst bubbles releases energy (luminescence, high temperature and pressure, shock waves, etc.) locally, and this energy removes polishing debris and abrasive particles of a polishing liquid from the surface of the substrate W. In addition, because the gas-liquid interface of the gas dissolved water has a negative potential, the gas dissolved water adsorbs and removes electrolyte ions and contamination with a positive potential.

The magnitude of the bubble impact depends on the bubble diameter. Therefore, when the gas dissolved water supplied on the polishing pad 84 is the gas dissolved water, the impact caused by the burst of bubbles in the gas dissolved water is greater than the impact caused by the burst of bubbles in the gas dissolved water.

In this embodiment, the substrate W is polished with the gas dissolved water. Therefore, the impact on the substrate W caused by the bubble burst is small. Since the substrate W may have a fine structure, the damage to the substrate W can be reduced by polishing the substrate W with gas dissolved water. As a result, defects in the substrate W can be prevented. Furthermore, this configuration does not require a longer processing time for the substrate W, and a throughput of the substrate W can be improved.

After terminating water polishing of the substrate W with the gas dissolved water, the controller 30 closes the open/close valves 154A to 154E, and opens the open/close valve 146 to supply pure water onto the polishing pad 84. Thereafter, the controller 30 rotates the polishing table 80 and the top ring 81 while the substrate W is adsorbed on the top ring 81 (see step S405). In this state, the controller 30 raises the top ring 81, and positions the top ring 81 above the polishing pad 84.

The controller 30 performs the supply preparation for stable supplying of the gas dissolved water in parallel with the substrate W transporting operation (i.e., step S405 and step S407 described below) (see step S406). More specifically, the controller 30 operates the three way valves 156A and 156B to close the bypass line 157 while opening a portion of the gas dissolved water supply line 152 (more specifically, upstream side of the three way valve 156A and downstream side of the three way valve 156B) in order to supply the gas dissolved water. The gas dissolved water then passes through the microbubble filter 159, and as a result, the substrate processing system 50 supplies the gas dissolved water containing microbubbles.

When the controller 30 closes the open/close valves 154A to 154E, and opens the open/close valve 155, the gas dissolved water is returned to the circulation line CL through the gas dissolved water supply line 152 without being supplied from the gas dissolved water nozzles 133A to 133E. The controller 30 determines whether the number of bubbles in the gas dissolved water is stable based on the number of bubbles measured by the particle counter 160.

After step S405, the controller 30 moves the top ring 81 with the substrate W adsorbed outside the polishing pad 84 to transport the substrate W to a next process (see step S407). After step S407, the controller 30 dresses the polishing pad 84 by supplying the gas dissolved water onto the polishing pad 84 while moving the dresser 115 onto the polishing pad 84 (see step S408).

During dressing of the polishing pad 84, the controller 30 may inject a large flow rate of cleaning liquid from the atomizer 85 arranged above the polishing pad 84 onto the surface of the polishing pad 84. In one embodiment, the flow rate of the gas dissolved water supplied from the nozzle arm 130 is 1 L/min, and the flow rate of the gas dissolved water supplied from the atomizer 85 is 10 L/min.

In this embodiment, the substrate processing system 50 is configured to supply gas dissolved water through the nozzle arm 130. In one embodiment, the substrate processing system 50 may be configured to supply the gas dissolved water through the atomizer 85. With this configuration, the substrate processing system 50 can not only supply the gas dissolved water through the nozzle arm 130, but also supply a large flow rate of gas dissolved water onto the polishing pad 84 through the atomizer 85. The structure for supplying the gas dissolved water from the atomizer 85 is the same as the structure for supplying the gas dissolved water from the nozzle arm 130 (or the structure for the above described embodiments (FIGS. 1 through 14)), so the description is omitted.

During dressing of the polishing pad 84, the substrate processing system 50 supplies the gas dissolved water onto the polishing pad 84. More specifically, the controller 30 opens at least one of the open/close valves 154A to 154E, and closes the open/close valve 155 to supply the gas dissolved water containing microbubbles from at least one of the gas dissolved water nozzles 133A to 133E onto the polishing pad 84.

As described above, the impact caused by the bursting of bubbles in the gas dissolved water is greater than the impact caused by the bursting of bubbles in the gas dissolved water. Therefore, the substrate processing system 50 can cause a greater impact on the front surface (polishing surface) of the polishing pad 84 due to the bursting of the bubbles.

This configuration can more reliably eliminate clogging of the polishing pad 84. Therefore, the amount of polishing pad 84 scraped off can be reduced during dressing of the polishing pad 84. As a result, a longer life of the polishing pad 84 can be achieved, and the polishing rate and a profile of the substrate W are not adversely affected. Furthermore, dressing time can be reduced and throughput can be improved.

According to this embodiment, the substrate processing system 50 can stabilize the polishing process of the substrate W by supplying the gas dissolved water with high cleaning power (i.e., the gas dissolved water, the gas dissolved water) on the polishing pad 84 after the polishing of the substrate W is terminated.

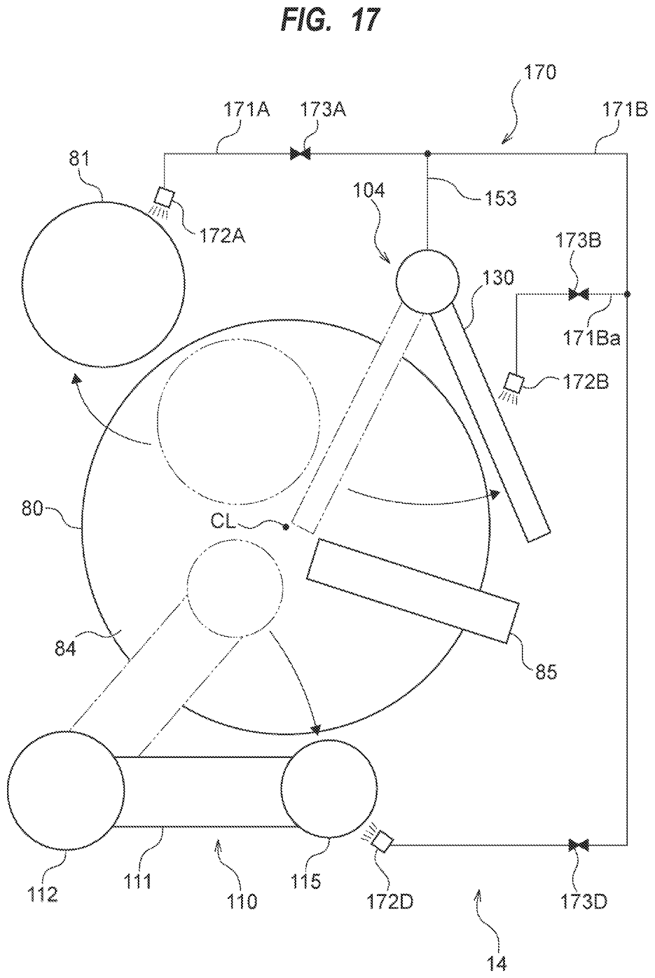

FIG. 17 is a view showing another embodiment of the polishing apparatus. As shown in FIG. 17, the substrate processing system 50 may include a gas dissolved water distribution system 170 that distributes the gas dissolved water to the components of the polishing module 14 (in this embodiment, top ring 81, liquid supply mechanism 104, and dressing device 110).

The gas dissolved water distribution system 170 includes a distribution line 171A connected to the gas dissolved water supply line 152, a cleaning nozzle 172A connected to the distribution line 171A, and an open/close valve 173A connected to the distribution line 171A.

The cleaning nozzle 172A is arranged adjacent to the top ring 81 in the retreated position, and the substrate processing system 50 injects the gas dissolved water from below the top ring 81 toward the top ring 81. The injection of gas dissolved water with high cleaning power can clean the top ring 81 more effectively.

As shown in step S409 of FIG. 16, after transporting the substrate W, the controller 30 moves the top ring 81 to the retreated position located outside the polishing pad 84, and supplies the gas dissolved water to the top ring 81 arranged at the retreated position to clean the top ring 81. Since the substrate processing system 50 cleans the top ring 81 while the top ring 81 is arranged in the retreated position, the gas dissolved water that cleans the top ring 81 can be prevented from falling on the polishing pad 84.

The open/close valve 173A is electrically connected to the controller 30. The controller 30 closes the open/close valves 154A to 154E while opening the open/close valve 155 (see FIG. 15) and the open/close valve 173A to supply the gas dissolved water onto the top ring 81. In step S408, the substrate processing system 50 supplies the gas dissolved water, and in step S409, the substrate processing system 50 also supplies the gas dissolved water onto the top ring 81.

As shown in FIG. 17, the gas dissolved water distribution system 170 may include a distribution line 171B connected to the gas dissolved water supply line 152, and cleaning nozzles 172B and 172D connected to the distribution line 171B.

The cleaning nozzle 172B is arranged adjacent to the nozzle arm 130 arranged in the retreated position. A branch line 171Ba branched from the distribution line 171B is connected to the cleaning nozzle 172B, and an open/close valve 173B is connected to the branch line 171Ba.

The cleaning nozzle 172D is arranged adjacent to the dresser 115, which is arranged in the retreated position. An open/close valve 1173D connected to the distribution line 171B is arranged adjacent to the cleaning nozzle 172D.

The controller 30 can close the open/close valves 154A to 154E while opening the open/close valve 155 and the open/close valves 173B and 173D to supply the gas dissolved water onto the nozzle arm 130 and the dresser 115. For example, the controller 30 may clean at least one of the nozzle arms 130 and the dresser 115 as well as the top ring 81 in step S409 of FIG. 16.

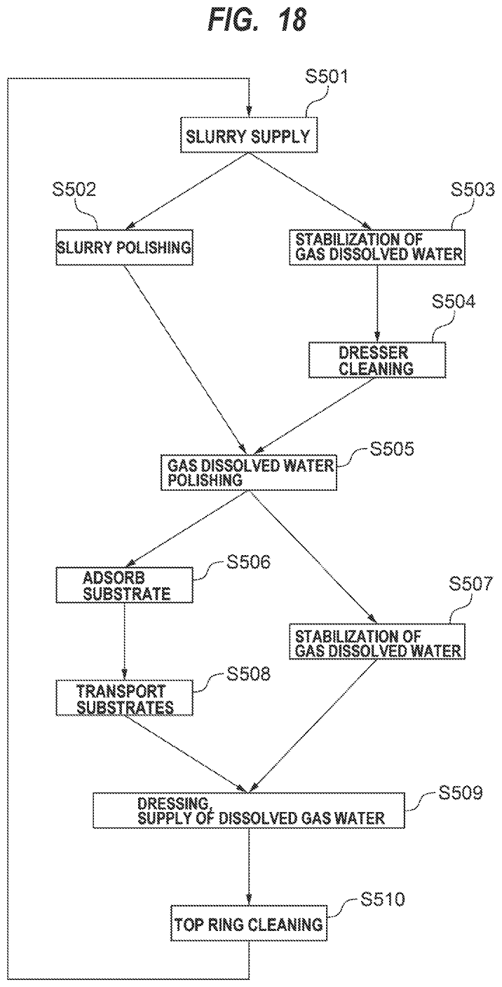

FIG. 18 is a view showing another embodiment of the processing flow of the substrate by the controller. As shown in FIG. 18, the controller 30 supplies the slurry onto the polishing pad 84 to slurry polish the substrate W (see steps S501 and S502). The controller 30 may perform a supply preparation for stable supplying of the gas dissolved water in parallel with the polishing operation of the substrate W (i.e., step S502) (see step S503), and supply the gas dissolved water to the dresser 115 through the gas dissolved water distribution device 170 (see step S504). In one embodiment, the controller 30 may clean not only the dresser 115 but also the atomizer 85.

The controller 30 then starts the gas dissolved water polishing of the substrate W (see step S505), and after step S505 is terminated, the controller 30 absorbs the substrate W onto the top ring 81 (see step S506).

As shown in step S507, the controller 30 performs the supply preparation for stable supplying of the gas dissolved water in parallel with the transporting operation of the substrate W (i.e., step S506 and step S508 described below), and after the substrate W is transported to the next process (see step S508), the gas dissolved water is supplied onto the polishing pad 84 to dress the polishing pad 84 (see step S509).

After transporting the substrate W, the controller 30 supplies the gas dissolved water to the top ring 81 arranged in the retreated position to clean the top ring 81 (see step S510). In the embodiment shown in FIG. 18, since the dresser 115 is cleaned in step S504, the substrate processing system 50 does not need to clean the dresser 115 in step S510.

Although not shown, the embodiment shown in FIGS. 1 through 14 and that of FIGS. 15 through 18 may be combined as appropriate.

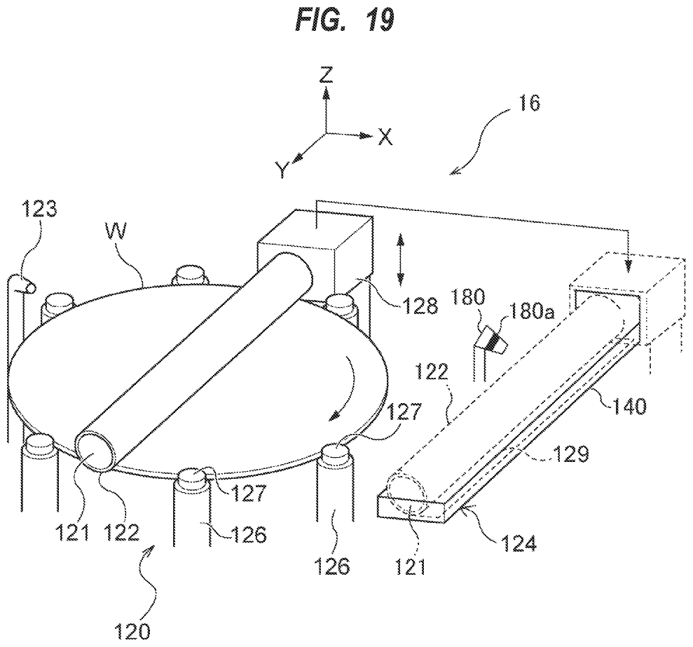

FIG. 19 is a view showing another embodiment of the first cleaning module. As shown in FIG. 19, the first cleaning module 16 includes a spin chuck 120 that holds and rotates the substrate W, a cleaning roller 121 longer than the diameter of the substrate W, a cleaning member 122 wrapped around the cleaning roller 121, a cleaning liquid nozzle 123 that supplies the cleaning liquid toward the front surface of the substrate W, and a support column 128 that movably supports the cleaning roller 121.

In the embodiment shown in FIG. 19, the cleaning roller 121 and the cleaning member 122 have a configuration corresponding to the cleaning members 61 and 62 (see FIG. 3) described above. The spin chuck 120 includes a piece 127 that holds the peripheral portion of the substrate W, and a spindle 126 that rotatably holds the piece 127.

In this embodiment, the spin chuck 120 includes a plurality of spindles 126 and a number of pieces 127 corresponding to the number of spindles 126. When the piece 127 held at an upper end of the spindle 126 rotates, a rotational force of the piece 127 is transmitted to the substrate W, and the substrate W rotates with the piece 127.

The first cleaning module 16 includes a self-cleaning section 124 arranged at a self-cleaning position (standby position of the cleaning roller 121 and the cleaning member 122) away from the position of the cleaned substrate W, and a processing liquid supply nozzle (self-cleaning liquid nozzle) 180 arranged in the self-cleaning section 124.

The self-cleaning section 124 is arranged adjacent to the spin chuck 120. The support column 128 is movable in an X, Y, and Z directions shown in FIG. 19. Therefore, the support column 128 is configured to move the cleaning roller 121 between the substrate cleaning position where the spin chuck 120 is arranged and the self-cleaning position where the self-cleaning section 124 is arranged.

The cleaning liquid nozzle 123 supplies the cleaning liquid onto the front surface of the substrate W held by the spin chuck 120, and the cleaning member 122 (and cleaning roller 121) arranged on the substrate W scrubs the front surface of the rotating substrate W (see, for example, step S104 in FIG. 10). Particles contained in the cleaning liquid supplied from the cleaning liquid nozzle 123 adhere to the cleaning member 122 by scrubbing the substrate W.

Therefore, after the scrub cleaning of the substrate W is terminated, the support column 128 moves the cleaning roller 121 from the substrate cleaning position to the self-cleaning position (see an arrow in FIG. 19). The cleaning roller 121 (and cleaning member 122) moved to the self-cleaning position is cleaned in the self-cleaning section 124 by the cleaning liquid supplied from the self-cleaning liquid nozzle 180.

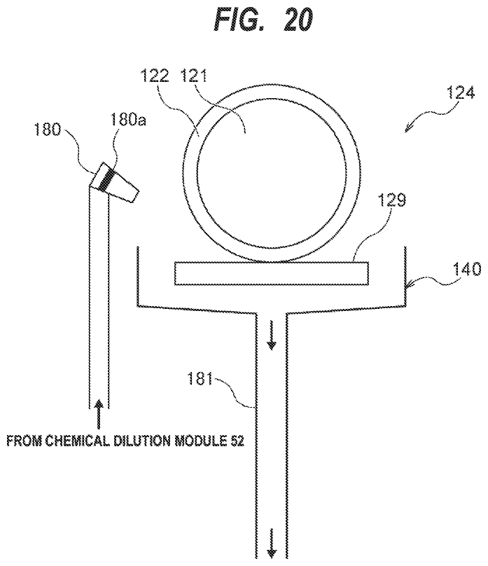

FIG. 20 is a cross-sectional view showing the first cleaning module shown in FIG. 19. As shown in FIG. 20, the self-cleaning section 124 includes a self-cleaning tank 140 that receives the cleaning liquid supplied from the self-cleaning liquid nozzle 180, a drainage pipe 181 that discharges the cleaning liquid supplied to the self-cleaning tank 140, and a quartz plate 129 arranged in the self-cleaning tank 140.

The self-cleaning liquid nozzle 180 has a decompression release portion 180a that reduces the pressure of the cleaning liquid supplied from the chemical dilution module 52. The decompression release portion 180a has the same configuration as the decompression release portions described above (e.g., decompression release portions 65a, 66a, 67a, and 68a).

The self-cleaning liquid nozzle (i.e., processing liquid supply nozzle) 180 supplies cleaning liquid containing fine bubbles or gas dissolved water containing fine bubbles toward the cleaning member 122 (i.e., scrub processing member) that is waiting in the self-cleaning position. The fine bubbles are generated by the decompression release portion 180a. In this manner, the self-cleaning liquid nozzle 180 removes particles adhering to the cleaning member 122. The cleaning member 122 may be pressed against the quartz, plate 129 to facilitate removal of particles from the cleaning member 122 during cleaning of the cleaning member 122.

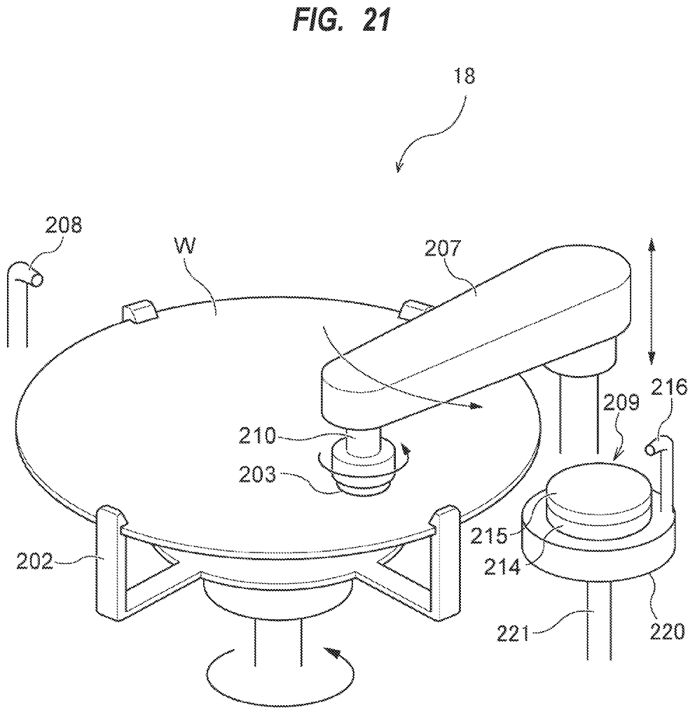

FIG. 21 is view showing another embodiment of the second cleaning module. As shown in FIG. 21, the second cleaning module 18 includes a spin chuck 202 that holds and rotates the substrate W, a cleaning member 203 (i.e., a scrub processing member) that scrubs the substrate W, a rotational shaft 210 that rotatably supports the cleaning member 203, a swinging arm 207 that swings the cleaning member 203 via the rotational shaft 210, and a cleaning liquid nozzle 208 that supplies the cleaning liquid onto the front surface of the substrate W.

When the substrate W is held by the spin chuck 202 and the spin chuck 202 rotates, the substrate W rotates with the spin chuck 202. The cleaning liquid nozzle 208 supplies the cleaning liquid onto the front surface of the substrate W held by the spin chuck 202, and the cleaning member 203 arranged on the substrate W scrub cleans the front surface of the substrate W (see, for example, step S104 in FIG. 10). Particles contained in the cleaning liquid supplied from the cleaning liquid nozzle 208 adhere to the cleaning member 203 by scrubbing the substrate W.

The second cleaning module 18 includes a self-cleaning section 209 arranged at a self-cleaning position (standby position of the cleaning member 203) away from the position of the cleaned substrate W, and a processing liquid supply nozzle (self-cleaning liquid nozzle) 216 arranged in the self-cleaning section 209.

The self-cleaning section 209 is arranged adjacent to the spin chuck 202. The swinging arm 207 is configured to move the cleaning member 203 between the substrate cleaning position where the spin chuck 202 is arranged and the self-cleaning position where the self-cleaning section 209 is arranged.

After the scrub cleaning of the substrate W is terminated, the swinging arm 207 moves the cleaning member 203 from the substrate cleaning position to the self-cleaning position. The cleaning member 203 moved to the self-cleaning position is cleaned in the self-cleaning section 209.

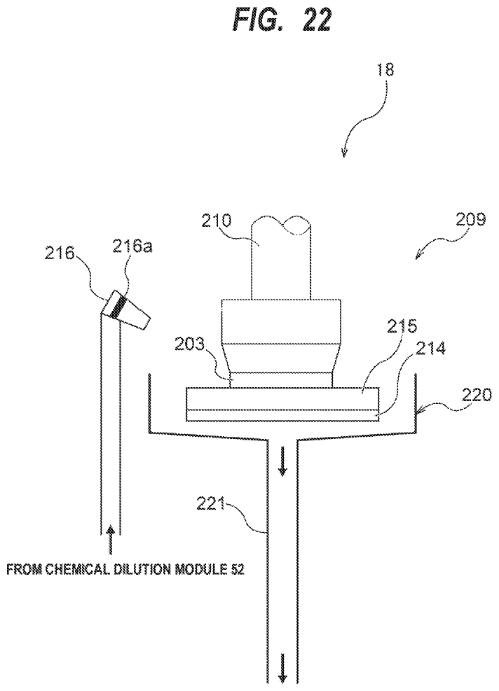

FIG. 22 is a cross-sectional view of the second cleaning module shown in FIG. 21. As shown in FIG. 22, the self-cleaning liquid nozzle 216 has a decompression release portion 216a that reduces the pressure of the cleaning liquid supplied from the chemical liquid dilution module 52. The decompression release portion 216a has the same configuration as the decompression release portions described above (e.g., decompression release portions 65a, 66a. 67a, and 68a).

As shown in FIG. 22, the self-cleaning section 209 includes a self-cleaning tank 220 that receives the cleaning liquid supplied from the self-cleaning liquid nozzle 216, a drainage pipe 221 that discharges the cleaning liquid supplied to the self-cleaning tank 220, a quartz plate 215 arranged in the self-cleaning tank 220, and a support plate 214 that supports the quartz plate 215. The support plate 214 is fixed to a support shaft not shown.

The self-cleaning liquid nozzle 216 (i.e., the processing liquid supply nozzle) supplies the cleaning liquid containing fine bubbles or the gas dissolved water containing fine bubbles toward the cleaning member 203 (i.e., the scrub processing member) that is waiting in the self-cleaning position. The fine bubbles are generated by the decompression release portion 216a. In this manner, the self-cleaning liquid nozzle 216 removes particles adhering to the cleaning member 203 by scrubbing the substrate W. The cleaning member 203 may be pressed against the quartz plate 215 during the cleaning of the cleaning member 203.

Although not shown. FIGS. 19 through 22 may be applied to FIGS. 1 through 18, as appropriate. For example, the self-cleaning section 124 and the processing liquid supply nozzle 180 described with reference to FIGS. 19 and 20 may be applied to the first cleaning module 16 described with reference to FIG. 3. Similarly, the self-cleaning section 209 and the processing liquid supply nozzles 216 described with reference to FIGS. 21 and 22 may be applied to the second cleaning module 18 described with reference to FIG. 4.

The previous description of embodiments is provided to enable a person skilled in the art to make and use the present invention. Moreover, various modifications to these embodiments will be readily apparent to those skilled in the art, and the generic principles and specific examples defined herein may be applied to other embodiments. Therefore, the present invention is not intended to be limited to the embodiments described herein but is to be accorded the widest scope as defined by limitation of the claims.

1. A substrate processing system comprising:
a gas dissolved water generation tank configured to dissolve a gas in pure water at a first pressure;
a chemical liquid dilution module configured to mix a chemical liquid and a gas dissolved water generated in the gas dissolved water generation tank at a predetermined volume ratio; and
a substrate processing module configured to process a substrate,
wherein the substrate processing module comprises:
a substrate holding mechanism configured to hold the substrate;
a scrub processing member configured to contact the substrate and scrub the substrate; and
a processing liquid supply nozzle configured to supply a processing liquid onto the substrate,
wherein the processing liquid supply nozzle has a decompression release portion that generates fine bubbles of the gas from a diluted chemical liquid by decompressing the diluted chemical liquid mixed in the chemical liquid dilution module from the first pressure to a second pressure, and
the processing liquid supply nozzle supplies the diluted chemical liquid containing the fine bubbles in a process of scrubbing the substrate.

2. The substrate processing system according to claim 1, wherein the decompression release portion composes at least one or more orifice plates arranged in an internal flow path of the processing liquid supply nozzle or in a flow path immediately of the processing liquid supply nozzle, and
wherein the orifice plate reduces a pressure of the diluted chemical liquid to the second pressure by a pressure loss effect of the orifice plate, and simultaneously generates the fine bubbles.

3. The substrate processing system according to claim 1, wherein the substrate processing system comprises a gas supply source, a pure water supply source, and a water supply pump arranged in a flow path on upstream side of the gas dissolved water generation tank, and
wherein the water supply pump is configured to transfer pure water to the gas dissolved water generation tank so that a pressure in the gas dissolved water generation tank becomes the first pressure.

4. The substrate processing system according to claim 1, wherein the gas is composed of at least one or more of nitrogen, hydrogen, oxygen, ozone, carbon dioxide, neon, argon, xenon, and krypton.

5. The substrate processing system according to claim 1, wherein the substrate processing system comprises a liquid supply pump arranged in a flow path on upstream side of the chemical liquid dilution module, and
wherein the liquid supply pump is configured to transfer the chemical liquid to the chemical liquid dilution module to achieve the first pressure.

6. The substrate processing system according to claim 1, wherein the substrate processing module comprises a cleaning module,
wherein the chemical liquid is an undiluted cleaning liquid, and
wherein the scrub processing member comprises at least one of a sponge cleaning member and a buff cleaning member.

7. The substrate processing system according to claim 6, wherein the processing liquid supply nozzle, in the cleaning module, is arranged on a swinging arm configured to swing in a radial direction of the rotating substrate, and
wherein the processing liquid supply nozzle is configured to uniformly supply the cleaning liquid containing the fine bubbles from a center to a peripheral portion of the substrate.

8. The substrate processing system according to claim 6, wherein the processing liquid supply nozzle, in the cleaning module, is arranged on a self-cleaning position away from a position of the substrate, and
wherein the processing liquid supply nozzle is configured to supply the cleaning liquid containing the fine bubbles or the gas dissolved water containing the fine bubbles toward the scrub processing member waiting at the self-cleaning position.

9. The substrate processing system according to claim 1, wherein the substrate processing module comprises a polishing module,
wherein the chemical liquid is an undiluted slurry, and
wherein the scrub processing member comprises a polishing pad.

10. The substrate processing system according to claim 9, wherein the processing liquid supply nozzle, in the polishing module, is arranged above the rotating polishing pad, and
wherein the processing liquid supply nozzle is configured to supply the slurry containing the fine bubbles so as to infiltrate a contact interface between the rotating substrate and the polishing pad.

11. The substrate processing system according to claim 9, wherein the substrate processing system comprises a pure water supply nozzle having a decompression release portion configured to generate the fine bubbles from the gas dissolved water, and the decompression release portion extends in a radial direction of the polishing pad, and
wherein the pure water supply nozzle is configured to supply the gas dissolved water containing the fine bubbles during dressing of the polishing pad after terminating the polishing of the substrate.

12. The substrate processing system according to claim 9, wherein the substrate processing system comprises a single or a plurality of gas dissolved water nozzles configured to supply the gas dissolved water containing the fine bubbles onto the polishing pad, and arranged on a nozzle arm configured to be able to swing in a radial direction of the polishing pad, and
wherein the gas dissolved water nozzle is configured to supply the gas dissolved water containing the fine bubbles onto the polishing pad while the substrate is in contact with the polishing pad after terminating polishing the substrate.

13. A substrate processing method for processing a substrate, comprising:
dissolving a gas in pure water in a gas dissolved water generation tank at a first pressure;
mixing a chemical liquid and a gas dissolved water generated in the gas dissolved water generation tank in a chemical liquid dilution module at a predetermined volume ratio;
passing a diluted chemical liquid mixed in the chemical liquid dilution module through a decompression release portion arranged in an internal flow path of a processing liquid supply nozzle or a flow path immediately before the processing liquid supply nozzle to generate fine bubbles of the gas from the diluted chemical liquid by decompressing a pressure from the first pressure to a second pressure; and
supplying the diluted chemical liquid containing the fine bubbles in a process of scrubbing the substrate.

14. The substrate processing method according to claim 13, wherein the gas is composed of at least one or more of nitrogen, hydrogen, oxygen, ozone, carbon dioxide, neon, argon, xenon, and krypton.

15. The substrate processing method according to claim 13, wherein the chemical liquid is an undiluted cleaning liquid, and
wherein the substrate processing method comprises supplying the diluted chemical liquid containing the fine bubbles while bringing a scrub processing member comprising at least one of a sponge cleaning member and a buff cleaning member into contact with the substrate.

16. The substrate processing method according to claim 13, wherein the chemical liquid is an undiluted slurry, and
wherein the substrate processing method comprises supplying the diluted chemical liquid containing the fine bubbles while bringing a scrub processing member comprising a polishing pad into contact with the substrate.

17. The substrate processing method according to claim 16, comprising:
supplying the gas dissolved water containing the fine bubbles from a pure water supply nozzle having a decompression release portion configured to generate the fine bubbles from the gas dissolved water during dressing of the polishing pad after terminating the polishing of the substrate.

18. The substrate processing method according to claim 16, comprising:
supplying the gas dissolved water containing the fine bubbles from a single or a plurality of gas dissolved water nozzles onto the polishing pad while the substrate is in contact with the polishing pad after polishing of the substrate, and
wherein the gas dissolved water nozzle is arranged in a nozzle arm configured to be able to swing in a radial direction of the polishing pad.

19. The substrate processing method according to claim 15, comprising:
transporting the scrub processing member to a self-cleaning position away from a position of the substrate after scrubbing the substrate; and
supplying a cleaning liquid containing the fine bubbles or a gas dissolved water containing the fine bubbles toward the scrub processing member waiting at the self-cleaning position.
